(19) United States
(12) Patent Application Publication
(10) Pub. No.: US 2024/0429872 A1
(43) Pub. Date: Dec. 26, 2024

(54) ELECTRONIC CIRCUIT AND DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/825,500

(22) Filed: Sep. 5, 2024

Related U.S. Application Data
(63) Continuation of application No. PCT/JP2023/011934, filed on Mar. 24, 2023.

(30) Foreign Application Priority Data
Mar. 25, 2022 (JP) 2022-050618

(51) Int. Cl. H03F 1/02; H03F 3/45; H03G 1/00

(52) U.S. Cl. CPC H03F 1/0288; H03F 3/45085; H03G 1/0023; H03F 2200/09; H03F 2200/451

(57) ABSTRACT

An electronic circuit includes: a variable amplitude control circuit that controls an amplitude of a first radio-frequency signal being a single-ended signal in accordance with a control signal that continuously changes and that outputs a second radio-frequency signal being a single-ended signal; and a balun that converts the second radio-frequency signal into differential signals and outputs a pair of third radio-frequency signals.

### CROSS REFERENCE TO RELATED APPLICATION

This is a continuation of International Application No. PCT/JP2023/011934 filed on Mar. 24, 2023 which claims priority from Japanese Patent Application No. 2022-050618 filed on Mar. 25, 2022. The contents of these applications are incorporated herein by reference in their entireties.

### BACKGROUND ART

### Technical Field

The present disclosure relates to an electronic circuit and a Doherty amplifier circuit.

In radio-frequency circuits, a circuit that controls the amplitude of a radio-frequency signal (hereinafter referred to as an RF signal in some cases) in accordance with an external control signal is implemented by a variable gain amplifier. Furthermore, a circuit that controls the amplitude of a differential RF signal in accordance with an external control signal is implemented by a differential variable gain amplifier.

However, in an existing differential variable gain amplifier, the frequency of an amplitude control signal (hereinafter referred to as a Base Band (BB) signal in some cases) increases with an increase in the frequency of an RF signal, and an issue has become pronounced. For example, an issue arises in a case where a BB signal is a single-ended signal as in the following Patent Document 1.
Patent Document 1: Japanese Patent No. 3822503

### BRIEF SUMMARY

In a differential variable gain amplifier disclosed in Patent Document 1, source potentials of two transistors constituting a differential pair are changed by a variable resistor that is controlled by a BB signal. These source potentials are amplified and are output as common mode signals. There is a possibility that those common mode signals may adversely affect a subsequent circuit.

In view of the above, the present disclosure has been made to reduce a common mode signal component of a differential radio-frequency signal.

An electronic circuit according to an aspect of the present disclosure includes: a variable amplitude control circuit that controls an amplitude of a first radio-frequency signal being a single-ended signal in accordance with a control signal that continuously changes and that outputs a second radio-frequency signal being a single-ended signal; and a balun that converts the second radio-frequency signal into differential signals and outputs a pair of third radio-frequency signals.

A Doherty amplifier circuit according to an aspect of the present disclosure includes: at least one-stage carrier amplifier that amplifies a fifth radio-frequency signal split from a fourth radio-frequency signal; and at least one-stage peaking amplifier that amplifies a sixth radio-frequency signal split from the fourth radio-frequency signal and different from the fifth radio-frequency signal in phase. At least one of the at least one-stage carrier amplifier and the at least one-stage peaking amplifier is the electronic circuit according to the present disclosure.

A Doherty amplifier circuit according to an aspect of the present disclosure includes: at least one-stage carrier amplifier that amplifies a fifth radio-frequency signal split from a fourth radio-frequency signal; at least one-stage peaking amplifier that amplifies a sixth radio-frequency signal split from the fourth radio-frequency signal and different from the fifth radio-frequency signal in phase; at least one bias circuit that supplies a bias to the at least one-stage peaking amplifier; and the electronic circuit according to the present disclosure that controls an amplitude of at least one of the fourth radio-frequency signal to the sixth radio-frequency signal in accordance with a saturation signal representing saturation of the at least one-stage carrier amplifier or the at least one-stage peaking amplifier, that converts the at least one of the fourth radio-frequency signal to the sixth radio-frequency signal into differential signals, that detects the differential signals, and that outputs a detected signal to the at least one bias circuit.

The present disclosure enables a common mode signal component of a differential radio-frequency signal to be reduced.

### BRIEF DESCRIPTION OF THE DRAWINGS

FIG. 1 is a diagram illustrating an overview of a differential variable amplitude control circuit according to a comparative example.

FIG. 2 is a diagram illustrating an example of a frequency spectrum of an output signal of the differential variable amplitude control circuit according to the comparative example.

FIG. 3 is a diagram illustrating an overview of an electronic circuit according to a first embodiment.

FIG. 4 is a diagram illustrating an example of a frequency spectrum of an output signal of the electronic circuit according to the first embodiment.

FIG. 5 is a diagram illustrating a circuit configuration of the electronic circuit according to the first embodiment.

FIG. 6 is a diagram illustrating an example of a frequency spectrum of an output signal of a variable amplitude control circuit in the electronic circuit according to the first embodiment.

FIG. 7 is a diagram illustrating an example of a frequency spectrum of an output signal of a balun in the electronic circuit according to the first embodiment.

FIG. 8 is a diagram illustrating a circuit configuration of an electronic circuit according to a second embodiment.

FIG. 9 is a diagram illustrating a circuit configuration of an electronic circuit according to a third embodiment.

FIG. 10 is a diagram illustrating a circuit configuration of an electronic circuit according to a fourth embodiment.

FIG. 11 is a diagram illustrating a circuit configuration of an electronic circuit according to a fifth embodiment.

FIG. 12 is a diagram illustrating a configuration of a Doherty amplifier circuit according to a sixth embodiment.

FIG. 13 is a diagram illustrating a configuration of a Doherty amplifier circuit according to a seventh embodiment.

FIG. 14 is a diagram illustrating a circuit configuration of an electronic circuit according to an eighth embodiment.

### DETAILED DESCRIPTION

Embodiments of an electronic circuit and a Doherty amplifier circuit according to the present disclosure will be described in detail below with reference to the drawings. Note that the present disclosure is not to be limited by these embodiments. The embodiments are merely illustrative, and it goes without necessarily saying that configurations described in different embodiments can be partially replaced or combined. In second and subsequent embodiments, a description of things in common with a first embodiment is omitted, and only respects in which the second and subsequent embodiments differ from the first embodiment will be described. In particular, similar function effects achieved by similar configurations are not repeatedly described in each embodiment.

### First Embodiment

Although a first embodiment will be described below, a comparative example will be described first to facilitate understanding of the first embodiment.

### Comparative Example

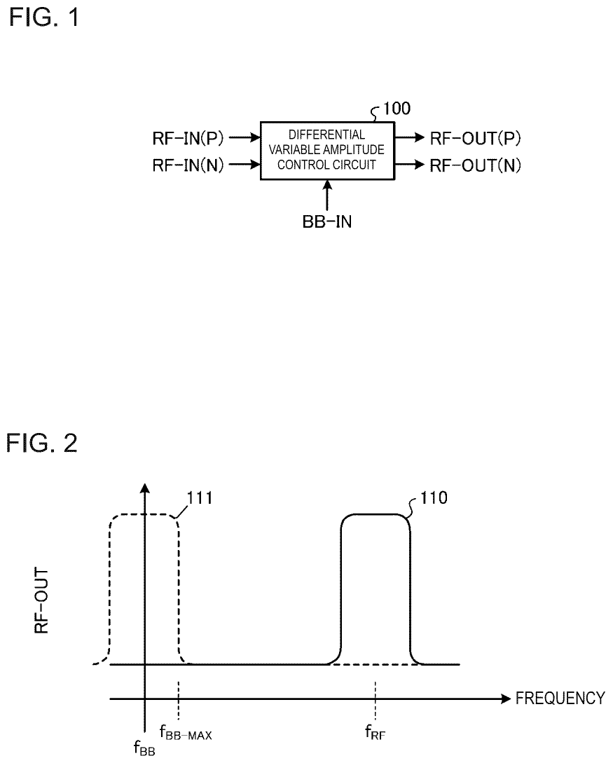

FIG. 1 is a diagram illustrating an overview of a differential variable amplitude control circuit according to a comparative example.

Radio-frequency signals RF-IN(P) and RF-IN(N), which are differential signals, are input to a differential variable amplitude control circuit 100. Furthermore, a signal BB-IN, which is a single-ended amplitude control signal, is input to the differential variable amplitude control circuit 100. The differential variable amplitude control circuit 100 controls amplitudes of the radio-frequency signals RF-IN(P) and RF-IN(N) in accordance with the signal BB-IN and outputs radio-frequency signals RF-OUT(P) and RF-OUT(N), which are differential signals.

Hereinafter, in some cases, the radio-frequency signals RF-IN(P) and RF-IN(N) are collectively referred to as a radio-frequency signal RF-IN, and the radio-frequency signals RF-OUT(P) and RF-OUT(N) are collectively referred to as a radio-frequency signal RF-OUT.

FIG. 2 is a diagram illustrating an example of a frequency spectrum of an output signal of the differential variable amplitude control circuit according to the comparative example.

A radio-frequency signal RF-OUT includes a differential mode signal component (differential component) represented by a waveform 110, and a common mode signal component (in-phase component) represented by a waveform 111.

The differential mode signal component represented by the waveform 110 has a frequency component of the radio-frequency signal RF-IN centered at a frequency f_{RF}. The common mode signal component represented by the waveform 111 has a frequency component of the signal BB-IN centered at a frequency f_{BB}. A maximum frequency of the frequency component of the signal BB-IN is a frequency f_{BB}-MAX.

For example, if a differential detector circuit is connected to a stage subsequent to the differential variable amplitude control circuit 100, since the radio-frequency signal RF-OUT includes the common mode signal component, detection accuracy of the differential detector circuit decreases.

If the frequency f_{BB-MAX} is less than 1% of the frequency f_{RF}, the frequency component of the signal BB-IN can be removed by a capacitor for cutting off a bias. However, if the frequency f_{BB-MAX} is not less than 1% of the frequency f_{RF} due to an increase in the frequency of the radio-frequency signal RF-IN seen in recent years, a filter has to be provided separately to remove the frequency component of the signal BB-IN.

### Overview of First Embodiment

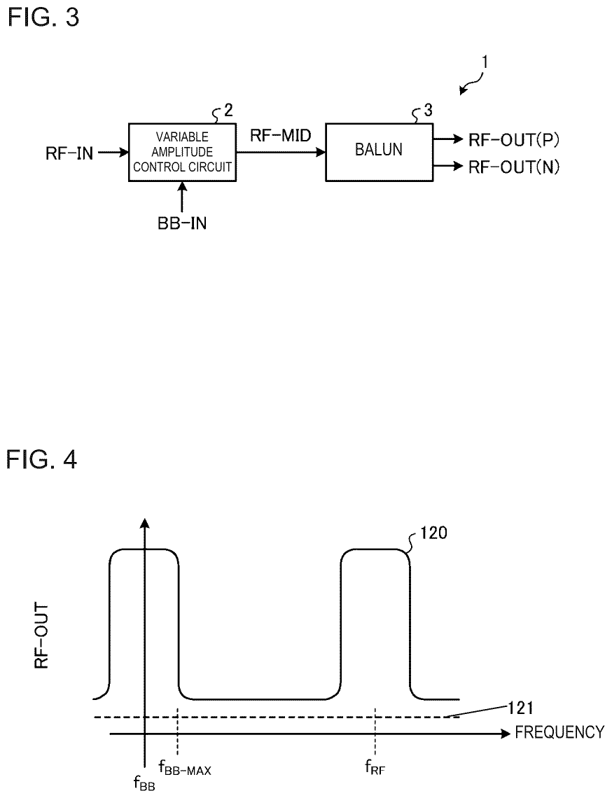

FIG. 3 is a diagram illustrating an overview of an electronic circuit according to the first embodiment.

An electronic circuit 1 includes a variable amplitude control circuit 2 and a balun 3.

Although, as an example of the variable amplitude control circuit 2, a variable gain amplifier or a variable attenuator is given, the present disclosure is not limited to this.

A radio-frequency signal RF-IN, which is a single-ended signal, is input to the variable amplitude control circuit 2. Furthermore, a signal BB-IN, which is a single-ended amplitude control signal, is input to the variable amplitude control circuit 2. The variable amplitude control circuit 2 controls an amplitude of the radio-frequency signal RF-IN in accordance with the signal BB-IN and outputs a radio-frequency signal RF-MID, which is a single-ended signal, to the balun 3.

The balun 3 converts the radio-frequency signal RF-MID, which is a single-ended signal, into differential signals and outputs radio-frequency signals RF-OUT(P) and RF-OUT(N), which are the differential signals.

FIG. 4 is a diagram illustrating an example of a frequency spectrum of an output signal of the electronic circuit according to the first embodiment.

A radio-frequency signal RF-OUT includes a differential mode signal component represented by a waveform 120, and a common mode signal component represented by a waveform 121.

The differential mode signal component represented by the waveform 120 has a frequency component of the radio-frequency signal RF-IN centered at a frequency f_{RF}, and a frequency component of the signal BB-IN centered at a frequency f_{BB}. The common mode signal component represented by the waveform 121 is constant at a low level over an entire frequency range.

The signal BB-IN can leak into an output terminal of the variable amplitude control circuit 2. That is, the frequency component of the signal BB-IN can be included in the radio-frequency signal RF-MID.

For example, if the balun 3 is a balun, such as an active balun, that has broadband characteristics, the balun 3 also converts a signal component of the signal BB-IN included in the radio-frequency signal RF-MID into differential signals. For this reason, the differential mode signal component represented by the waveform 120 has the frequency component centered at the frequency f_{BB}.

Furthermore, for example, if the balun 3 is a balun that has narrowband characteristics centered at the frequency f_{RF}, the balun 3 removes a signal component of the signal BB-IN included in the radio-frequency signal RF-MID and does not output the signal component.

Hence, even if the balun 3 is either of the above-described types, the radio-frequency signal RF-OUT is kept from including a signal component of the common mode signal BB-IN.

Thus, in the electronic circuit 1, for example, even if a differential detector circuit is connected to a stage subsequent to the balun 3, since the radio-frequency signal RF-OUT does not include any signal component of the common mode signal BB-IN, a decrease in detection accuracy of the differential detector circuit can be reduced.

In the electronic circuit 1, even if a frequency f_{BB-MAX} is not less than 1% of the frequency f_{RF}, an output error from the differential detector circuit in the subsequent stage can be reduced without necessarily using any filter separately.

Incidentally, for example, a case is examined where it is desired to obtain a signal obtained by adding information on the signal BB-IN to an envelope signal of the radio-frequency signal RF-IN. In general, as the simplest way to obtain a signal of interest, an envelope signal of the radio-frequency signal RF-IN is obtained by a detector circuit, and the envelope signal and the signal BB-IN are added by an adder.

However, when the frequencies of the envelope signal and the signal BB-IN increase, the adder is unable to follow the increases, and no signal of interest can be obtained.

Thus, in the electronic circuit 1 according to the first embodiment, the amplitude of the radio-frequency signal RF-IN is controlled in accordance with the signal BB-IN, and the radio-frequency signal whose amplitude has been controlled is converted into differential signals, thereby enabling detection by the circuit in the subsequent stage and making it possible to obtain a signal of interest.

Note the occurrence of a malfunction if a high frequency component is included in the signal BB-IN. As described later, the electronic circuit 1 according to the first embodiment can respond even if a high frequency component is included in the signal BB-IN.

### Overall Configuration of First Embodiment

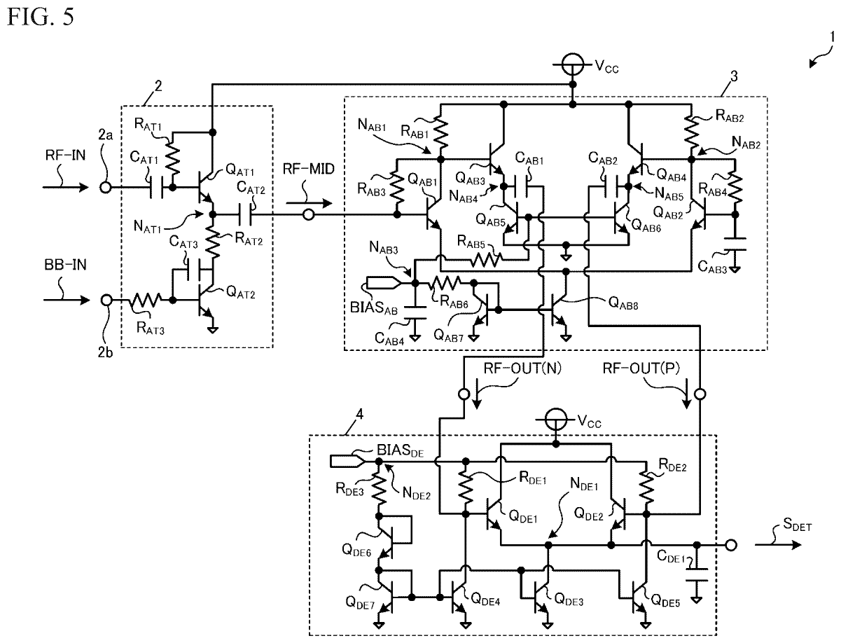

FIG. 5 is a diagram illustrating a circuit configuration of the electronic circuit according to the first embodiment.

The electronic circuit 1 includes the variable amplitude control circuit 2 and the balun 3. In the first embodiment, although the balun 3 is an active balun, the present disclosure is not limited to this.

Furthermore, in the first embodiment, although the electronic circuit 1 includes a detector circuit 4, the present disclosure is not limited to this. The detector circuit 4 detects a radio-frequency signal RF-OUT input from the balun 3 and outputs a detected signal S_{DET}.

### (Circuit Configuration of Variable Amplitude Control Circuit)

The variable amplitude control circuit 2 includes transistors Q_{AT1} and Q_{AT2}, resistors R_{AT1}, R_{AT2}, and R_{AT3}, and capacitors C_{AT1}, C_{AT2}, and C_{AT3}.

The transistor Q_{AT1} corresponds to an example of “fourth transistor” in the present disclosure. The transistor Q_{AT2} corresponds to an example of “fifth transistor” in the present disclosure. The capacitor C_{AT3} corresponds to an example of “first capacitor” in the present disclosure.

In the present disclosure, although each transistor is a bipolar transistor, the present disclosure is not limited to this. Although, as an example of the bipolar transistor, a Heterojunction Bipolar Transistor (HBT) is given, the present disclosure is not limited to this. The transistor may be, for example, a Field Effect Transistor (FET). The transistor may be a multi-finger transistor including a plurality of unit transistors electrically connected in parallel. A unit transistor refers to a minimum component constituting the transistor.

If each transistor is an FET, the drain, gate, and source of the FET respectively correspond to the collector, base, and emitter of the bipolar transistor.

A collector of the transistor Q_{AT1} is electrically connected to a power supply potential Vcc and receives a supply of power. A base of the transistor Q_{AT1} is electrically connected to the power supply potential Vcc via the resistor R_{AT1} and is biased. An emitter of the transistor Q_{AT1} is electrically connected to a node N_{AT1}.

The node N_{AT1} is an output node of the transistor Q_{AT1}.

The base of the transistor Q_{AT1} is electrically connected to an input terminal 2a via the capacitor C_{AT1}, which is a DC cut capacitor. A radio-frequency signal RF-IN, which is a single-ended signal, is input to the input terminal 2a. Thus, the radio-frequency signal RF-IN is input to the base of the transistor Q_{AT1}, the transistor Q_{AT1} amplifies the radio-frequency signal RF-IN and outputs a radio-frequency signal RF-MID from the emitter to the node N_{AT1}.

The radio-frequency signal RF-IN corresponds to an example of “first radio-frequency signal” in the present disclosure.

An emitter of the transistor Q_{AT2} is electrically connected to a reference potential. That is, the transistor Q_{AT2} is emitter-grounded. Although, as an example of the reference potential, a ground potential is given, the present disclosure is not limited to this. A collector of the transistor Q_{AT2} is electrically connected to the node N_{AT1} via the resistor R_{AT2}. A base of the transistor Q_{AT2} is electrically connected to an input terminal 2b via the resistor R_{AT3}. A signal BB-IN, which is a single-ended amplitude control signal, is input to the input terminal 2b. Thus, the signal BB-IN is input to the base of the transistor Q_{AT2}.

The signal BB-IN corresponds to an example of “control signal” in the present disclosure.

In the present disclosure, the signal BB-IN is a signal that continuously changes and is continuously supplied. That is, the signal BB-IN is input to the transistor Q_{AT2} at all times and can continuously take on values from a first value that controls the transistor Q_{AT2} so as to put the transistor Q_{AT2} into a non-conducting (cutoff) state to a second value that controls the transistor Q_{AT2} so as to put the transistor Q_{AT2} into a conducting (saturation) state.

One end of the capacitor C_{AT3} is electrically connected to the base of the transistor Q_{AT2}. The other end of the capacitor C_{AT3} is electrically connected to the collector of the transistor Q_{AT2}. Thus, negative feedback is applied to the transistor Q_{AT2} at a frequency of the radio-frequency signal RF-IN.

One end of the capacitor C_{AT2}, which is a DC cut capacitor, is electrically connected to the node N_{AT1}. From the other end of the capacitor C_{AT2}, a single-ended radio-frequency signal RF-MID obtained by controlling the amplitude of the radio-frequency signal RF-IN in accordance with the signal BB-IN is output to the balun 3.

The radio-frequency signal RF-MID corresponds to an example of “second radio-frequency signal” in the present disclosure.

### (Operation of Variable Amplitude Control Circuit)

The transistor Q_{AT1} is connected to the resistor R_{AT2} and the transistor Q_{AT2} so as to establish an emitter-follower connection. In the variable amplitude control circuit 2, the transistor Q_{AT1} operates as an emitter follower to thereby perform current amplification.

The transistor Q_{AT2} is controlled in response to a signal value of the signal BB-IN so as to be brought into conduction or non-conduction. In the present disclosure, note that, since the signal BB-IN is a signal that continuously changes and is continuously supplied, the transistor Q_{AT2} is continuously controlled between conduction and non-conduction.

For example, when the transistor Q_{AT2} enters a conducting state, an emitter bias current flows to the transistor Q_{AT1}, and thus transistor Q_{AT1} performs current amplification. On the other hand, when the transistor Q_{AT2} enters a non-conducting state, no emitter bias current flows to the transistor Q_{AT1}, and thus the transistor Q_{AT1} does not perform current amplification. That is, the variable amplitude control circuit 2 is a circuit that can control the amplitude of the radio-frequency signal RF-IN in response to the signal BB-IN.

Hence, the variable amplitude control circuit 2 has characteristics in which the variable amplitude control circuit 2 increases the radio-frequency signal RF-MID when the signal BB-IN increases and in which the variable amplitude control circuit 2 reduces the radio-frequency signal RF-MID when the signal BB-IN decreases.

Thus, in the variable amplitude control circuit 2, the signal BB-IN is a signal that continuously changes and is supplied, therefor facilitating a reduction in deterioration of the quality of an output signal from the variable amplitude control circuit 2. For example, if the signal BB-IN is a signal that discretely changes and is supplied (for example, if a variable amplitude control circuit is switched between an operating state and a non-operating state with a switch or the like for use), a waveform of an output signal from the variable amplitude control circuit discontinuously changes. At this time, there is a possibility that an unwanted signal may be caused by a discontinuous change in an output signal waveform and the quality of an output signal from the variable amplitude control circuit may decrease. On the other hand, in the variable amplitude control circuit 2 according to this embodiment, since the signal BB-IN is a signal that continuously changes and is supplied, a waveform of an output signal from the variable amplitude control circuit 2 also continuously changes, and unwanted noise is less likely to be caused.

The variable amplitude control circuit 2 can control the amplitude of the radio-frequency signal RF-IN fast by using the transistor Q_{AT1} connected so as to establish an emitter-follower connection.

Furthermore, the variable amplitude control circuit 2 includes the capacitor C_{AT3}, thereby making it possible to reduce the occurrence of a malfunction.

For example, a radio-frequency signal RF-IN that has leaked can be input to the input terminal 2b to which the signal BB-IN is input.

If there is no capacitor C_{AT3}, since the transistor Q_{AT2} is emitter-grounded, the transistor Q_{AT2} amplifies the radio-frequency signal RF-IN that has leaked. Subsequently, the radio-frequency signal amplified by the transistor Q_{AT2} and the radio-frequency signal RF-MID amplified by the transistor Q_{AT1} mix at the node N_{AT1} and interfere with each other, and the variable amplitude control circuit 2 can malfunction.

Thus, the variable amplitude control circuit 2 includes the capacitor C_{AT3} electrically connected between the base and collector of the transistor Q_{AT2}. In the variable amplitude control circuit 2, the capacitor C_{AT3} Can reduce the gain of the transistor Q_{AT2} with its emitter grounded at the frequency of the radio-frequency signal RF-IN. Consequently, the variable amplitude control circuit 2 can reduce the above-described interference and reduce the occurrence of a malfunction.

### (Circuit Configuration of Balun)

The balun 3 includes transistors Q_{AB1} to Q_{AB8}, resistors R_{AB1} to R_{AB6}, and capacitors C_{AB1} to C_{AB4}.

The transistors Q_{AB1} and Q_{AB2} correspond to an example of “a pair of sixth transistors” in the present disclosure. The transistors Q_{AB3} and Q_{AB4} correspond to an example of “a pair of seventh transistors” in the present disclosure. The transistor Q_{AB8} corresponds to an example of “eighth transistor” in the present disclosure. The transistors Q_{AB5} and Q_{AB6} correspond to an example of “ninth transistor” in the present disclosure. The capacitor C_{AB3} corresponds to an example of “second capacitor” in the present disclosure. In this embodiment, note that, although “ninth transistor” refers to a pair of transistors Q_{AB5} and Q_{AB6}, the number of “ninth transistors” is not limited to this. For example, either the transistor Q_{AB5} or Q_{AB6} may be omitted.

The transistors Q_{AB1} and Q_{AB2} are transistors constituting a differential pair. The transistors Q_{AB3} and Q_{AB4} are output transistors. The transistors Q_{AB5} to Q_{AB8} are transistors that supply a bias to the transistors Q_{AB1} to Q_{AB4}.

One end of the resistor R_{AB1} is electrically connected to the power supply potential Vcc. The other end of the resistor R_{AB1} is electrically connected to a node N_{AB1}. A collector of the transistor Q_{AB1} is electrically connected to the node N_{AB1}. The collector of the transistor Q_{AB1} is electrically connected to the power supply potential Vcc via the resistor R_{AB1} and receives a supply of power.

The node N_{AB1} is an output node of the transistor Q_{AB1}.

One end of the resistor R_{AB3} is electrically connected to the node N_{AB1}. The other end of the resistor R_{AB3} is electrically connected to a base of the transistor Q_{AB1}. The base of the transistor Q_{AB1} is electrically connected to the power supply potential Vcc via the resistors R_{AB1} and R_{AB3} and is biased. The radio-frequency signal RF-MID is input from the variable amplitude control circuit 2 to the base of the transistor Q_{AB1}.

One end of the resistor R_{AB2} is electrically connected to the power supply potential Vcc. The other end of the resistor R_{AB2} is electrically connected to a node N_{AB2}. A collector of the transistor Q_{AB2} is electrically connected to the node N_{AB2}. The collector of the transistor Q_{AB2} is electrically connected to the power supply potential Vcc via the resistor R_{AB2} and receives a supply of power.

The node N_{AB2} is an output node of the transistor Q_{AB2}.

One end of the resistor RABA is electrically connected to the node N_{AB2}. The other end of the resistor RABA is electrically connected to a base of the transistor Q_{AB2}. The base of the transistor Q_{AB2} is electrically connected to the power supply potential Vcc via the resistors R_{AB2} and R_{AB4} and is biased. One end of the capacitor C_{AB3} is electrically connected to the base of the transistor Q_{AB2}. The other end of the capacitor C_{AB3} is electrically connected to the reference potential.

One end of the resistor R_{AB6} is electrically connected to a node N_{AB3}. The other end of the resistor R_{AB6} is electrically connected to a collector and a base of the transistor Q_{AB7}. An emitter of the transistor Q_{AB7} is electrically connected to the reference potential. That is, the transistor Q_{AB7} is diode-connected.

A bias current BIAS_{AB} is supplied to the node N_{AB3}. The resistor R_{AB6} and the transistor Q_{AB7} generate a fixed potential at the node N_{AB3}.

One end of the capacitor C_{AB4} is electrically connected to the node N_{AB3}. The other end of the capacitor C_{AB4} is electrically connected to the reference potential. The capacitor C_{AB4} stabilizes a potential of the node N_{AB3}. An emitter of the transistor Q_{AB8} is electrically connected to the reference potential. A base of the transistor Q_{AB8} is electrically connected to the collector and base of the transistor Q_{AB7}. That is, the transistor Q_{AB8} is connected to the transistor Q_{AB2} so as to establish a current-mirror connection. A collector of the transistor Q_{AB8} is electrically connected to an emitter of the transistor Q_{AB1} and an emitter of the transistor Q_{AB2}. The transistor Q_{AB8} supplies a bias to the emitter of the transistor Q_{AB1} and the emitter of the transistor Q_{AB2}.

Thus, the transistor Q_{AB1} is emitter-grounded. On the other hand, the transistor Q_{AB2} is base-grounded by the capacitor C_{AB3}.

A collector of the transistor Q_{AB3} is electrically connected to the power supply potential Vcc and receives a supply of power. A base of the transistor Q_{AB3} is electrically connected to the node N_{AB1}. An emitter of the transistor Q_{AB3} is electrically connected to a node N_{AB4}.

A collector of the transistor Q_{AB5} is electrically connected to the node N_{AB4}. An emitter of the transistor Q_{AB5} is electrically connected to the reference potential. One end of the resistor R_{AB5} is electrically connected to the node N_{AB3}. The other end of the resistor R_{AB5} is electrically connected to a base of the transistor Q_{AB5}. That is, the transistor Q_{AB5} is connected to the transistor Q_{AB2} so as to establish a current-mirror connection. The transistor Q_{AB5} supplies a bias to the emitter of the transistor Q_{AB3}.

A collector of the transistor Q_{AB4} is electrically connected to the power supply potential Vcc and receives a supply of power. A base of the transistor Q_{AB4} is electrically connected to the node N_{AB2}. An emitter of the transistor Q_{AB4} is electrically connected to a node N_{AB5}.

A collector of the transistor Q_{AB6} is electrically connected to the node N_{AB5}. An emitter of the transistor Q_{AB6} is electrically connected to the reference potential. The other end of the resistor R_{AB5} is electrically connected to a base of the transistor Q_{AB6}. That is, the transistor Q_{AB6} is connected to the transistor Q_{AB7} so as to establish a current-mirror connection. The transistor Q_{AB6} supplies a bias to the emitter of the transistor Q_{AB4}.

One end of the capacitor C_{AB2}, which is a DC cut capacitor, is electrically connected to the node N_{AB5}. From the other end of the capacitor C_{AB2}, a radio-frequency signal RF-OUT(P) is output to the detector circuit 4.

One end of the capacitor C_{AB1}, which is a DC cut capacitor, is electrically connected to the node N_{AB1}. From the other end of the capacitor C_{AB4}, a radio-frequency signal RF-OUT(N) is output to the detector circuit 4.

The radio-frequency signals RF-OUT(P) and RF-OUT(N) correspond to an example of “a pair of third radio-frequency signals” in the present disclosure.

### (Operation of Balun)

The transistor Q_{AB1} operates with its emitter grounded. The transistor Q_{AB2} operates with its base grounded, and an emitter current of the transistor Q_{AB1} is input to the emitter of the transistor Q_{AB2}. Thus, signals having opposite phases are obtained from the collector of the transistor Q_{AB1} (node N_{AB1}) and the collector of the transistor Q_{AB2} (node N_{AB2}). That is, a differential pair of transistors Q_{AB1} and Q_{AB2} provide a voltage gain, convert the radio-frequency signal RF-MID into differential signals, and output the radio-frequency signals RF-OUT(P) and RF-OUT(N).

The balun 3 has characteristics in which the balun 3 increases the radio-frequency signals RF-OUT(P) and RF-OUT(N) when the radio-frequency signal RF-MID increases and in which the balun 3 reduces the radio-frequency signals RF-OUT(P) and RF-OUT(N) when the radio-frequency signal RF-MID decreases.

If an input impedance of a circuit in the stage subsequent to the balun 3 is high, output signals from the collector of the transistor Q_{AB1} (node N_{AB1}) and the collector of the transistor Q_{AB2} (node N_{AB2}) may be regarded as output signals of the balun 3.

In this case, note that there is a possibility that the output signals from the collector of the transistor Q_{AB1} and the collector of the transistor Q_{AB2} may be reduced, for example, by stray capacitances generated at the nodes N_{AB1} and N_{AB2}.

Thus, the balun 3 includes the transistors Q_{AB3} and Q_{AB4}, which are output transistors. Each of the transistors Q_{AB3} and Q_{AB4} operates as an emitter follower. For this reason, the balun 3 can output the radio-frequency signals RF-OUT(P) and RF-OUT(N) obtained by the transistors Q_{AB3} and Q_{AB4} amplifying the respective output signals from the collector of the transistor Q_{AB1} and the collector of the transistor Q_{AB2}. In other words, the transistors Q_{AB3} and Q_{AB4} can reduce impedances of loads on the collector of the transistor Q_{AB1} and the collector of the transistor Q_{AB2}.

Bias points of the transistors Q_{AB3} and Q_{AB4} are determined by the transistors Q_{AB5} and Q_{AB6} that are connected to the transistor Q_{AB2} so as to establish a current-mirror connection.

The balun 3 is an active balun that can convert an in-phase signal into differential signals over a wide frequency band including a low-frequency region if the electrostatic capacity of the capacitor C_{AB3} for implementing amplification by the transistor Q_{AB2} with its base grounded is increased. That is, the balun 3 can also convert the input signal BB-IN into differential signals and output the differential signals. Thus, no common mode signal BB-IN appears in the radio-frequency signals RF-OUT(P) and RF-OUT(N).

### (Configuration of Detector Circuit)

The detector circuit 4 includes transistors Q_{DE1} to Q_{DE7}, resistors R_{DE1} to R_{DE3}, and a capacitor C_{DE1}.

The transistors Q_{DE1} and Q_{DE2} are transistors constituting a differential pair.

The transistors Q_{DE1} and Q_{DE2} correspond to an example of “a pair of first transistors” in the present disclosure.

The transistors Q_{DE3} to Q_{DE7} and the resistors R_{DE1} to R_{DE3} supply a bias to bases and emitters of the transistors Q_{DE1} and Q_{DE2}.

Collectors of the transistors Q_{DE1} and Q_{DE2} are electrically connected to the power supply potential Vcc and receive a supply of power. The emitters of the transistors Q_{DE1} and Q_{DE2} are electrically connected to a node N_{DE1}.

The node N_{DE1} is an output node of the transistors Q_{DE1} and Q_{DE2}.

One end of the resistor R_{DE3}, one end of the resistor R_{DE1}, and one end of the resistor R_{DE2} are electrically connected to a node N_{DE2}.

The other end of the resistor R_{DE3} is electrically connected to a collector and a base of the transistor Q_{DE6}. That is, the transistor Q_{DE6} is diode-connected. An emitter of the transistor Q_{DE6} is electrically connected to a collector and a base of the transistor Q_{DE7}. That is, the transistor Q_{DE7} is diode-connected. An emitter of the transistor Q_{DE7} is electrically connected to the reference potential.

A bias current BIAS_{DE} is input to the node N_{DE2}. The resistor R_{DE3}, the transistor Q_{DE6}, and the transistor Q_{DE7} generate a fixed voltage. This voltage is input to the base of the transistor Q_{DE1} via the resistor R_{DE1} and is also input to the base of the transistor Q_{DE2} via the resistor R_{DE2}.

Each of the transistors Q_{DE3}, Q_{DE4}, and Q_{DE5} is connected to the transistor Q_{DE7} so as to establish a current-mirror connection.

A collector of the transistor Q_{DE4} is electrically connected to the base of the transistor Q_{DE1}. Thus, the transistor Q_{DE4} can adjust a base current of the transistor Q_{DE1}.

A collector of the transistor Q_{DE5} is electrically connected to the base of the transistor Q_{DE2}. Thus, the transistor Q_{DE5} can adjust a base current of the transistor Q_{DE2}.

A collector of the transistor Q_{DE3} is electrically connected to the node N_{DE1}. Thus, the transistor Q_{DE3} Can adjust emitter currents of the transistors Q_{DE1} and Q_{DE2}.

The radio-frequency signals RF-OUT(P) and RF-OUT(N) are respectively input to the base of the transistor Q_{DE2} and the base of the transistor Q_{DE1}.

One end of the capacitor C_{DE1} is electrically connected to the node N_{DE1}. The other end of the capacitor C_{DE1} is electrically connected to the reference potential.

The capacitor C_{DE1} is charged or discharged by a difference between the emitter currents of the transistors Q_{DE1} and Q_{DE2} and a collector current of the transistor Q_{DE3}. A voltage of the capacitor C_{DE1} is a detected signal S_{DET} obtained through detection of the radio-frequency signals RF-OUT(P) and RF-OUT(N). The capacitor C_{DE1} terminates a high frequency component (for example, a carrier frequency signal component) of the detected signal S_{DET} at the reference potential to remove the component and passes only a low frequency component.

### (Operation of Detector Circuit)

When the radio-frequency signal RF-OUT(P) is not less than a threshold voltage of the transistor Q_{DE2}, the transistor Q_{DE2} enters an ON state and outputs an emitter current. When the radio-frequency signal RF-OUT(N) is not less than a threshold voltage of the transistor Q_{DE1}, the transistor Q_{DE1} enters an ON state and outputs an emitter current.

That is, as amplitudes of the radio-frequency signals RF-OUT(P) and RF-OUT(N) increase (as the power of the radio-frequency signal RF-OUT increases), the emitter currents of the transistors Q_{DE1} and Q_{DE2} increase. Furthermore, as the amplitudes of the radio-frequency signals RF-OUT(P) and RF-OUT(N) decrease (as the power of the radio-frequency signal RF-OUT decreases), the emitter currents of the transistors Q_{DE1} and Q_{DE2} decrease.

The voltage of the capacitor C_{DE1} increases as the power of the radio-frequency signal RF-OUT increases. Furthermore, the voltage of the capacitor C_{DE1} decreases as the power of the radio-frequency signal RF-OUT decreases.

That is, the detector circuit 4 has characteristics in which the detector circuit 4 increases the detected signal S_{DET} when the radio-frequency signal RF-OUT increases and in which the detector circuit 4 reduces the detected signal S_{DET} when the radio-frequency signal RF-OUT decreases.

Thus, the detector circuit 4 can detect the radio-frequency signals RF-OUT(P) and RF-OUT(N) and output the detected signal S_{DET}.

### SUMMARY

(1) The variable amplitude control circuit 2 controls the amplitude of the radio-frequency signal RF-IN, which is a single-ended signal, in accordance with the signal BB-IN and outputs the radio-frequency signal RF-MID, which is a single-ended signal, to the balun 3. The balun 3 converts the radio-frequency signal RF-MID, which is a single-ended signal, into the radio-frequency signals RF-OUT(P) and RF-OUT(N), which are differential signals.

Note that the radio-frequency signal RF-MID can include a signal component of the signal BB-IN.

However, for example, if the balun 3 is a balun that has broadband characteristics, the balun 3 also converts a signal component of the signal BB-IN included in the radio-frequency signal RF-MID into differential signals.

Furthermore, for example, if the balun 3 is a balun that has narrowband characteristics, the balun 3 removes a signal component of the signal BB-IN included in the radio-frequency signal RF-MID and does not output the signal component.

Hence, even if the balun 3 is either of the above-described types, the electronic circuit 1 can keep the radio-frequency signals RF-OUT(P) and RF-OUT(N) from including a signal component of the common mode signal BB-IN.

Thus, in the electronic circuit 1, even if the detector circuit 4 is connected to the stage subsequent to the balun 3, since the radio-frequency signals RF-OUT(P) and RF-OUT(N) do not include any common mode signal component, a decrease in detection accuracy of the detector circuit 4 can be reduced.

(2) In comparison with a single-ended detector circuit, in the differential detector circuit 4, the number of times detection is performed doubles, and the electrostatic capacity of the capacitor C_{DE1} can be reduced to half, therefore enabling the detector circuit 4 to operate four times faster. Hence, the differential detector circuit 4 is indispensable to an application that expects fast operation.

However, in the detector circuit 4, an input terminal is connected to an output terminal in a direct-current (DC) manner (or via a stage of a capacitor for cutting off a bias). For that reason, the detector circuit 4 has characteristics in which, when a common mode signal is input, a malfunction in which the common mode signal leaks directly into the output terminal occurs.

Hence, as in a technique disclosed in Patent Document 1, when a circuit in which a control signal leaks into an output terminal as a common mode component is used in a stage preceding the detector circuit 4, a malfunction is caused.

On the other hand, in the electronic circuit 1, the variable amplitude control circuit 2 outputs, to the balun 3, the radio-frequency signal RF-MID obtained by controlling the amplitude of the single-ended radio-frequency signal RF-IN.

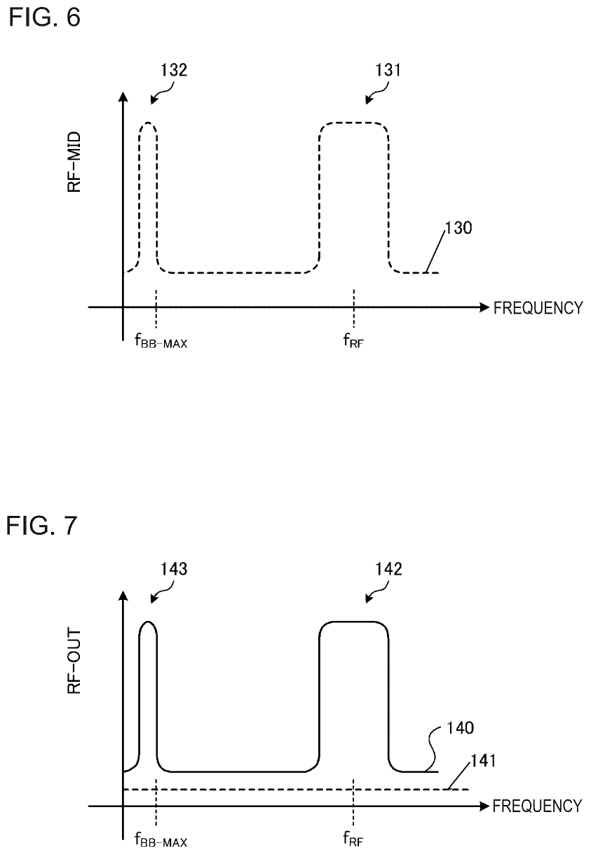

FIG. 6 is a diagram illustrating an example of a frequency spectrum of an output signal of the variable amplitude control circuit in the electronic circuit according to the first embodiment.

The radio-frequency signal RF-MID includes a common mode signal component represented by a waveform 130. The common mode signal component represented by the waveform 130 has a frequency component 131 of a radio-frequency signal centered at the frequency f_{RF}, and a frequency component 132 of the signal BB-IN of not more than the frequency f_{BB}-MAX.

The balun 3 is an active balun and converts a single-ended signal with up to a low frequency into differential signals.

FIG. 7 is a diagram illustrating an example of a frequency spectrum of an output signal of the balun in the electronic circuit according to the first embodiment.

The radio-frequency signal RF-OUT includes a differential mode signal component represented by a waveform 140, and a common mode signal component represented by a waveform 141. The differential mode signal component represented by the waveform 140 has a frequency component 142 of a radio-frequency signal centered at the frequency f_{RF}, and a frequency component 143 of the signal BB-IN of not more than the frequency f_{BB-MAX}. The common mode signal component represented by the waveform 141 is constant at a low level over an entire frequency range.

Thus, the electronic circuit 1 can keep a common mode signal from being input to the detector circuit 4, therefore enabling the detector circuit 4 to operate fast.

(3) Furthermore, the variable amplitude control circuit 2 includes the transistor Q_{AT1} having the collector electrically connected to the power supply potential Vcc, the base to which the radio-frequency signal RF-IN is input, and the emitter electrically connected to the node N_{AT1}. Additionally, the variable amplitude control circuit 2 includes the transistor Q_{AT2} having the collector electrically connected to the node N_{AT1}, the base to which the signal BB-IN is input, and the emitter electrically connected to the reference potential.

Note that the radio-frequency signal RF-IN can be input to the base of the transistor Q_{AT2}.

However, the variable amplitude control circuit 2 includes the capacitor C_{AT3} having one end electrically connected to the base of the transistor Q_{AT2} and the other end electrically connected to the collector of the transistor Q_{AT2}.

In the variable amplitude control circuit 2, the capacitor C_{AT3} can reduce the gain of the transistor Q_{AT2} with its emitter grounded at the frequency of the radio-frequency signal RF-IN.

Consequently, the variable amplitude control circuit 2 can keep a radio-frequency signal amplified by the transistor Q_{AT2} and a radio-frequency signal amplified by the transistor Q_{AT1} from mixing at the node NAM and interfering with each other. Hence, the electronic circuit 1 can reduce the occurrence of a malfunction.

(4) In the electronic circuit 1, even if the frequency f_{BB-MAX} is not less than 1% of the frequency f_{RF}, an output error from the detector circuit 4 can be reduced without necessarily using any filter separately.

(5) In the electronic circuit 1, in a frequency region not less than 1% of the frequency f_{RF}, even if the spectral density of the signal BB-IN is not less than 10% of the entire spectrum of the signal BB-IN, an output error from the detector circuit 4 can be reduced.

The electronic circuit 1 is more effective when the frequency of the radio-frequency signal RF-IN and the frequency of the signal BB-IN is closer to each other.

### Second Embodiment

The electronic circuit 1 according to the first embodiment has characteristics in which the electronic circuit 1 increases the detected signal S_{DET} when the radio-frequency signal RF-IN increases and in which the electronic circuit 1 reduces the detected signal S_{DET} when the radio-frequency signal RF-IN decreases.

On the other hand, an electronic circuit 1A according to a second embodiment has characteristics in which the electronic circuit 1A reduces the detected signal S_{DET} When the radio-frequency signal RF-IN increases and in which the electronic circuit 1A increases the detected signal S_{DET} When the radio-frequency signal RF-IN decreases.

### (Overall Configuration)

Of components in the second embodiment, components that are the same as components in the first embodiment are denoted by the same reference signs, and a description thereof is omitted.

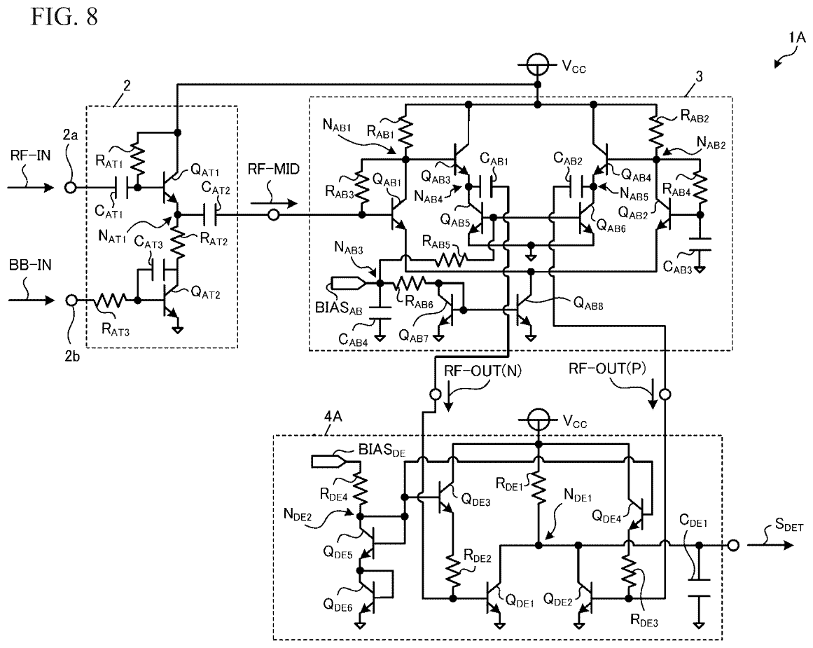

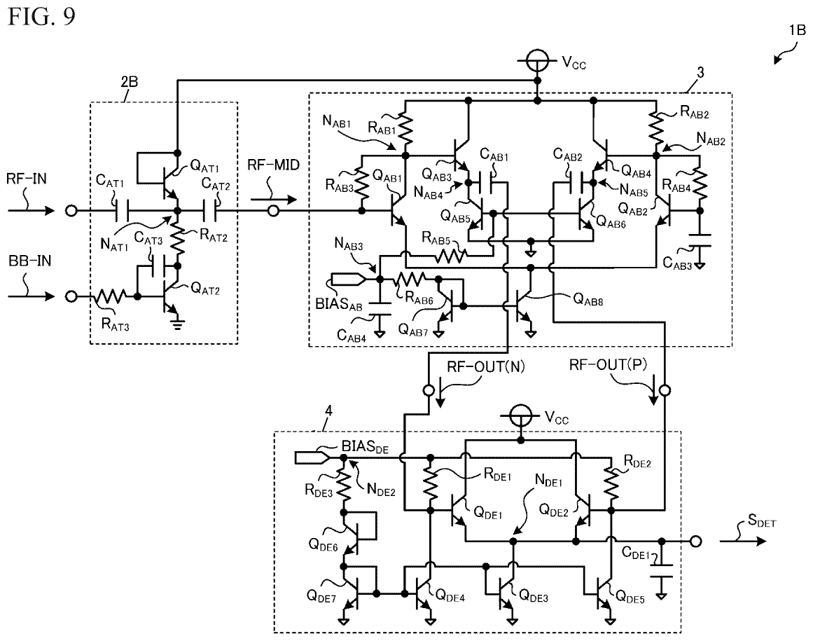

FIG. 8 is a diagram illustrating a circuit configuration of the electronic circuit according to the second embodiment.

In comparison with the electronic circuit 1 according to the first embodiment (see FIG. 5), the electronic circuit 1A according to the second embodiment includes a detector circuit 4A in place of the detector circuit 4.

### (Configuration of Detector Circuit)

The detector circuit 4A includes transistors Q_{DE1} to Q_{DE6}, resistors R_{DE1} to R_{DE4}, and the capacitor C_{DE1}.

The transistors Q_{DE1} and Q_{DE2} are transistors constituting a differential pair.

The transistors Q_{DE1} and Q_{DE2} correspond to an example of “a pair of first transistors” in the present disclosure.

The resistor R_{DE1} supplies a bias to the collectors of the transistors Q_{DE1} and Q_{DE2}.

The transistors Q_{DE3} to Q_{DE6} and the resistors R_{DE2} to R_{DE4} supply a bias to the bases of the transistors Q_{DE1} and Q_{DE2}.

One end of the resistor R_{DE1} is electrically connected to the power supply potential Vcc. The other end of the resistor R_{DE1} is electrically connected to the node N_{DE1}.

The collectors of the transistors Q_{DE1} and Q_{DE2} are electrically connected to the node N_{DE1} and receive a supply of power via the resistor R_{DE1}. The emitters of the transistors Q_{DE1} and Q_{DE2} are electrically connected to the reference potential.

The node N_{DE1} is an output node of the transistors Q_{DE1} and Q_{DE2}.

A bias current BIAS_{DE} is supplied to one end of the resistor R_{DE4}. The other end of the resistor R_{DE4} is electrically connected to the node N_{DE2}.

The collector and base of the transistor Q_{DE5} are electrically connected to the node N_{DE2}. That is, the transistor Q_{DE5} is diode-connected. An emitter of the transistor Q_{DE5} is electrically connected to the collector and base of the transistor Q_{DE6}. That is, the transistor Q_{DE6} is diode-connected. The emitter of the transistor Q_{DE6} is electrically connected to the reference potential.

The transistors Q_{DE5} and Q_{DE6} generate a fixed voltage at the node N_{DE2}. This voltage is input to a base of the transistor Q_{DE3} and a base of the transistor Q_{DE4}.

The collectors of the transistors Q_{DE3} and Q_{DE4} are electrically connected to the power supply potential Vcc and receive a supply of power.

An emitter of the transistor Q_{DE3} is electrically connected to one end of the resistor R_{DE2}. The other end of the resistor R_{DE2} is electrically connected to the base of the transistor Q_{DE1}. Thus, the transistor Q_{DE3} can adjust a base current of the transistor Q_{DE1}.

An emitter of the transistor Q_{DE4} is electrically connected to one end of the resistor R_{DE3}. The other end of the resistor R_{DE3} is electrically connected to the base of the transistor Q_{DE2}. Thus, the transistor Q_{DE4} can adjust a base current of the transistor Q_{DE2}.

The radio-frequency signals RF-OUT(P) and RF-OUT(N) are respectively input to the base of the transistor Q_{DE2} and the base of the transistor Q_{DE1}.

One end of the capacitor C_{DE1} is electrically connected to the node N_{DE1}. The other end of the capacitor C_{DE1} is electrically connected to the reference potential.

### (Operation of Detector Circuit)

Collector currents of the transistors Q_{DE1} and Q_{DE2} increase when the radio-frequency signal RF-OUT increases, a voltage drop across the resistor R_{DE1} increases, and thus a potential of the node N_{DE1} decreases. Collector currents of the transistors Q_{DE1} and Q_{DE2} decrease when the radio-frequency signal RF-OUT decreases, a voltage drop across the resistor R_{DE1} decreases, and thus a potential of the node N_{DE1} increases.

That is, the detector circuit 4A has characteristics in which the detected signal S_{DET} decreases when the radio-frequency signal RF-OUT increases and in which the detected signal S_{DET} increases when the radio-frequency signal RF-OUT decreases.

The variable amplitude control circuit 2 and the balun 3 in preceding stages have characteristics in which the variable amplitude control circuit 2 and the balun 3 increase the radio-frequency signal RF-OUT when the radio-frequency signal RF-IN increases and in which the variable amplitude control circuit 2 and the balun 3 reduce the radio-frequency signal RF-OUT when the radio-frequency signal RF-IN decreases.

Hence, the electronic circuit 1A has characteristics in which the electronic circuit 1A reduces the detected signal S_{DET} when the radio-frequency signal RF-IN increases and in which the electronic circuit 1A increases the detected signal S_{DET} when the radio-frequency signal RF-IN decreases.

The detector circuit 4 (see FIG. 5) or the detector circuit 4A only have to be selected in accordance with what detected signal S_{DET} a subsequent circuit asks for.

When a common mode signal is input to the detector circuit 4A, the detector circuit 4A outputs the common mode signal directly as in the detector circuit 4. Hence, it is desirable that the balun 3 be provided in a stage preceding the detector circuit 4A.

### Third Embodiment

The electronic circuit 1 according to the first embodiment and the electronic circuit 1A according to the second embodiment have characteristics in which the electronic circuit 1 and the electronic circuit 1A increase the radio-frequency signal RF-OUT when the signal BB-IN increases and in which the electronic circuit 1 and the electronic circuit 1A reduce the radio-frequency signal RF-OUT when the signal BB-IN decreases.

In some cases, however, characteristics are asked for in which the radio-frequency signal RF-OUT is reduced when the signal BB-IN increases and the radio-frequency signal RF-OUT is increased when the signal BB-IN decreases.

An electronic circuit 1B according to a third embodiment has such characteristics.

### (Overall Configuration)

Of components in the third embodiment, components that are the same as components in the other embodiments are denoted by the same reference signs, and a description thereof is omitted.

FIG. 9 is a diagram illustrating a circuit configuration of the electronic circuit according to the third embodiment.

In comparison with the electronic circuit 1 according to the first embodiment (see FIG. 5), the electronic circuit 1B according to the third embodiment includes a variable amplitude control circuit 2B in place of the variable amplitude control circuit 2.

### (Configuration of Variable Amplitude Control Circuit)

In comparison with the variable amplitude control circuit 2 (see FIG. 5), in the variable amplitude control circuit 2B, the base of transistor Q_{AT1} is electrically connected to its collector. That is, the transistor Q_{AT1} is diode-connected.

The transistor Q_{AT1} corresponds to an example of “fourth transistor” in the present disclosure. The transistor Q_{AT2} corresponds to an example of “fifth transistor” in the present disclosure.

### (Operation of Variable Amplitude Control Circuit)

When the signal BB-IN increases, the transistor Q_{AT2} enters a conducting state as in the variable amplitude control circuit 2, and a potential of the node N_{AT1} decreases. Thus, the transistor Q_{AT1} also enters a conducting state. The transistor Q_{AT1} is an emitter-follower amplifier circuit, and thus, when the transistor Q_{AT1} enters a conducting state, the transistor Q_{AT1} amplifies an input current signal and outputs the signal as a radio-frequency signal RF-MID.

When the signal BB-IN decreases, a current flowing to the collector of the transistor Q_{AT2} decreases. Thus, the transistor Q_{AT1} also enters a non-conducting state. As a result, the transistor Q_{AT1} does not perform emitter-follower amplification, and the signal of the radio-frequency signal RF-MID decreases.

Hence, the variable amplitude control circuit 2B has characteristics in which the variable amplitude control circuit 2B increases the radio-frequency signal RF-MID when the signal BB-IN increases and in which the variable amplitude control circuit 2B reduces the radio-frequency signal RF-MID when the signal BB-IN decreases.

The balun 3 has characteristics in which the balun 3 increases the radio-frequency signal RF-OUT when the radio-frequency signal RF-MID increases and in which the balun 3 reduces the radio-frequency signal RF-OUT when the radio-frequency signal RF-MID decreases.

Hence, the electronic circuit 1B has characteristics in which the electronic circuit 1B reduces the radio-frequency signal RF-OUT when the signal BB-IN increases and in which the electronic circuit 1B increases the radio-frequency signal RF-OUT when the signal BB-IN decreases.

Note that the third embodiment can be combined with the second embodiment. That is, the detector circuit 4 in the electronic circuit 1B may be replaced with the detector circuit 4A (see FIG. 8).

### Fourth Embodiment

If the power of the radio-frequency signal RF-IN is not small (is sufficiently large) for the sensitivity of the detector circuit, amplification by the active balun is optional.

An electronic circuit 1C according to a fourth embodiment includes, in place of an active balun, a balun using a transformer that is a passive element.

### (Overall Configuration)

Of components in the fourth embodiment, components that are the same as components in the other embodiments are denoted by the same reference signs, and a description thereof is omitted.

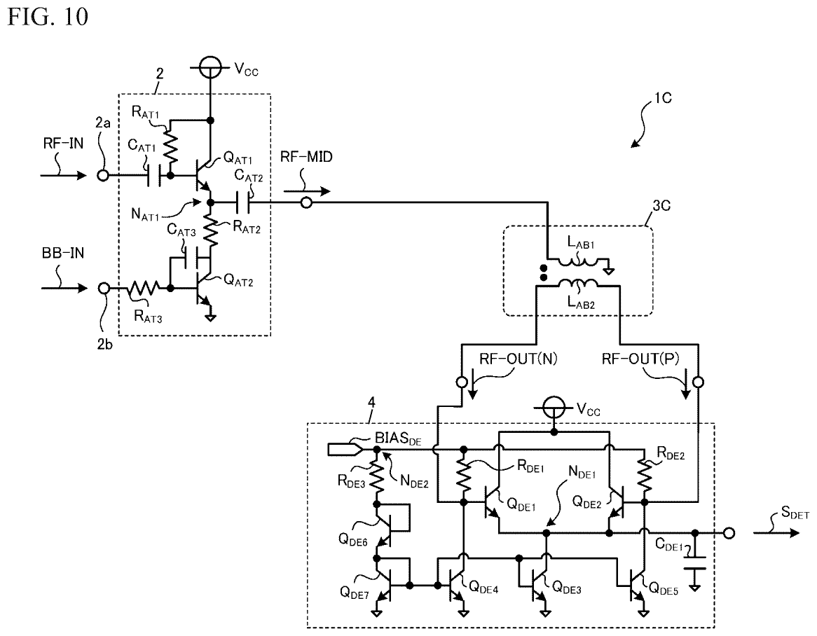

FIG. 10 is a diagram illustrating a circuit configuration of the electronic circuit according to the fourth embodiment.

### (Configuration and Operation of Balun)

In comparison with the electronic circuit 1 according to the first embodiment (see FIG. 5), the electronic circuit 1C according to the fourth embodiment includes a balun 3C in place of the balun 3.

The balun 3C includes a primary winding L_{AB1} and a secondary winding L_{AB2} that couple to each other via an electromagnetic field. The radio-frequency signal RF-MID is input to one end of the primary winding L_{AB1}. The other end of the primary winding L_{AB1} is electrically connected to the reference potential. The other end of the primary winding L_{AB1} may be electrically connected to a low-impedance circuit.

One end of the secondary winding L_{AB2} is electrically connected to the base of the transistor Q_{DE2} and outputs an induced radio-frequency signal RF-OUT(P) to the base of the transistor Q_{DE2}. The other end of the secondary winding L_{AB2} is electrically connected to the base of the transistor Q_{DE1} and outputs an induced radio-frequency signal RF-OUT(N) to the base of the transistor Q_{DE1}.

The balun 3C converts the radio-frequency signal RF-MID, which is a single ended-signal, into the radio-frequency signal RF-OUT, which refers to differential signals.

In comparison with the balun 3 (see FIG. 5), power consumption of the balun 3C can be reduced.

Note that the fourth embodiment can be combined with the second embodiment. That is, the detector circuit 4 in the electronic circuit 1C may be replaced with the detector circuit 4A (see FIG. 8).

Furthermore, the fourth embodiment can be combined with the third embodiment. That is, the variable amplitude control circuit 2 in the electronic circuit 1C may be replaced with the variable amplitude control circuit 2B (see FIG. 9).

### Fifth Embodiment

In the first to fourth embodiments, a circuit in the stage subsequent to the balun 3 or 3C is the detector circuit 4 or 4A. However, as a circuit that malfunctions when a common mode signal is input, a differential amplifier circuit is given as an example in addition to the detector circuit 4 or 4A.

When a common mode signal is input to two input terminals of the differential amplifier circuit, bias points of a differential pair of transistors connected to the input terminals simultaneously shift in the same direction. Thus, gains of the differential pair of transistors also change along with shifts of the bias points. For example, if the bias points of the differential pair of transistors shift and both the gains of the differential pair of transistors change into a high state, the gain of the differential amplifier circuit also changes into a high state, and no signal of interest can be obtained.

An electronic circuit 1D according to a fifth embodiment deals with the above-described issue.

### (Overall Configuration)

Of components in the fifth embodiment, components that are the same as components in the other embodiments are denoted by the same reference signs, and a description thereof is omitted.

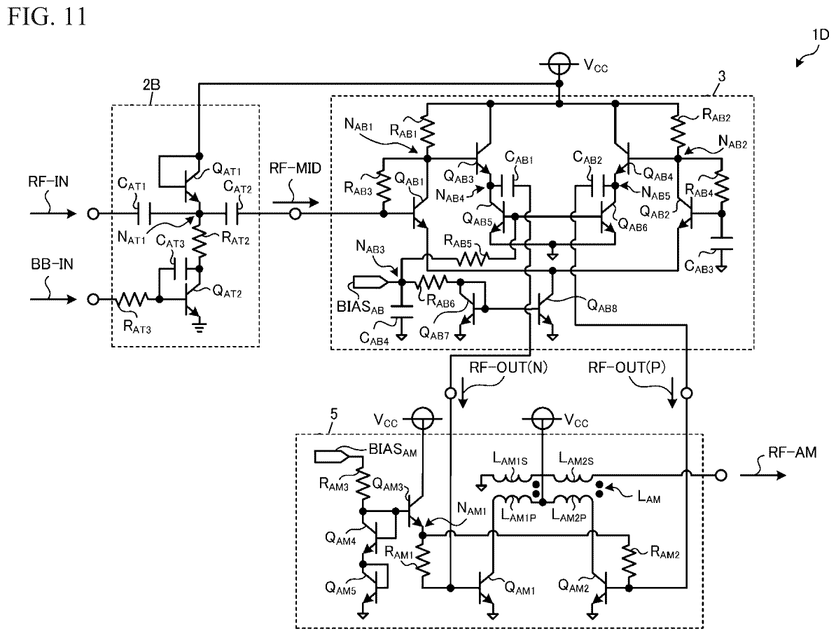

FIG. 11 is a diagram illustrating a circuit configuration of the electronic circuit according to the fifth embodiment.

In comparison with the electronic circuit 1B according to the third embodiment (see FIG. 9), the electronic circuit 1D according to the fifth embodiment includes a differential amplifier circuit 5 in place of the detector circuit 4.

### (Configuration and Operation of Differential Amplifier Circuit)

The differential amplifier circuit 5 includes transistors Q_{AM1} to Q_{AM5}, resistors R_{AM1} to R_{AM3}, and a transformer L_{AM}.

The transistors Q_{AM1} and Q_{AM2} are transistors constituting a differential pair. The transistors Q_{AM3} to Q_{AM5} and the resistors R_{AM1} to R_{AM3} supply a bias to bases of the transistors Q_{AM1} and Q_{AM2}.

The transistors Q_{AM1} and Q_{AM2} correspond to an example of “a pair of second transistors” in the present disclosure. The transistor Q_{AM3} corresponds to an example of “third transistor” in the present disclosure.

A bias current BIAS_{AM} is supplied to one end of the resistor R_{AM3}. The other end of the resistor R_{AM3} is electrically connected to a collector and a base of the transistor Q_{AM4}. That is, the transistor Q_{AM4} is diode-connected. An emitter of the transistor Q_{AM4} is electrically connected to a collector and a base of the transistor Q_{AM5}. That is, the transistor QAM is diode-connected. An emitter of the transistor Q_{AM5} is electrically connected to the reference potential.

The transistors Q_{AM4} and Q_{AM5} generate a fixed voltage. This voltage is input to a base of the transistor Q_{AM3}.

A collector of the transistor Q_{AM3} is electrically connected to the power supply potential Vcc and receives a supply of power. An emitter of the transistor Q_{AM3} is electrically connected to a node N_{AM1}.

One end of the resistor R_{AM1} is electrically connected to the node N_{AM1}. The other end of the resistor R_{AM1} is electrically connected to the base of the transistor Q_{AM1}. Thus, the transistor Q_{AM3} can adjust a base current of the transistor Q_{AM1}.

One end of the resistor R_{AM2} is electrically connected to the node N_{AM1}. The other end of the resistor R_{AM2} is electrically connected to the base of the transistor Q_{AM2}. Thus, the transistor Q_{AM3} can adjust a base current of the transistor Q_{AM2}.

The radio-frequency signals RF-OUT(P) and RF-OUT(N) are respectively input to the base of the transistor Q_{AM2} and the base of the transistor Q_{AM1}.

A primary winding of the transformer L_{AM} includes a winding L_{AM1P} and a winding L_{AM2P} that are connected in series.

One end of the winding L_{AM1P} is electrically connected to a collector of the transistor Q_{AM1}. The other end of the winding L_{AM1P} is electrically connected to one end of the winding L_{AM2P} and is also electrically connected to the power supply potential Vcc. The other end of the winding L_{AM2P} is electrically connected to a collector of the transistor Q_{AM2}.

A secondary winding of the transformer L_{AM} includes a winding L_{AM1S} and a winding L_{AM2S} that are connected in series and couples to the primary winding of the transformer L_{AM} via an electromagnetic field.

One end of the winding L_{AM1S} is electrically connected to the reference potential. The other end of the winding L_{AM1S} is electrically connected to one end of the winding L_{AM2S}. From the other end of the winding L_{AM2S}, a radio-frequency signal RF-AM, which is a single-ended signal, is output.

Even if the signal BB-IN is input from the balun 3 to the differential amplifier circuit 5, the signal BB-IN is input as differential signals. Hence, signals BB-IN that are differential signals pass through the resistors R_{AM1} and R_{AM2}, and combine and are consumed at the node N_{AM1} that is a virtual ground point.

Furthermore, even if the signals BB-IN that are differential signals are input to the respective bases of the transistors Q_{AM1} and Q_{AM2}, when a bias point of one transistor of the transistors Q_{AM1} and Q_{AM2} increases, a bias point of the other transistor of the transistors Q_{AM1} and Q_{AM2} decreases. That is, when the gain of one transistor of the transistors Q_{AM1} and Q_{AM2} increases, the gain of the other transistor of the transistors Q_{AM1} and Q_{AM2} decreases. Hence, in the differential amplifier circuit 5, as a whole, variations in the gains of the transistors Q_{AM1} and Q_{AM2} are cancelled out, and a stable gain can be maintained.

In the electronic circuit 1D, even if the frequency f_{BB}-MAX, which is the maximum frequency of the frequency component of the signal BB-IN, is not less than 1% of the frequency f_{RF}, a variation in gain of the differential amplifier circuit 5 can be reduced.

Note that the fifth embodiment can be combined with the first embodiment. That is, the variable amplitude control circuit 2B in the electronic circuit 1D may be replaced with the variable amplitude control circuit 2 (see FIG. 5).

Furthermore, the fifth embodiment can be combined with the fourth embodiment. That is, the balun 3 in the electronic circuit 1D may be replaced with the balun 3C.

Furthermore, although the differential amplifier circuit 5 outputs the radio-frequency signal RF-AM, which is a single-ended signal, the present disclosure is not limited to this. The differential amplifier circuit 5 may omit the transformer L_{AM} and output radio-frequency signals, which are differential signals.

Furthermore, although, in the differential amplifier circuit 5, one transistor Q_{AM3} supplies a bias to the bases of the transistors Q_{AM1} and Q_{AM2}, the present disclosure is not limited to this. In the differential amplifier circuit 5, two transistors may supply biases to the respective bases of the transistors Q_{AM1} and Q_{AM2}.

### Sixth Embodiment

Of components in a sixth embodiment, components that are the same as components in the other embodiments are denoted by the same reference signs, and a description thereof is omitted.

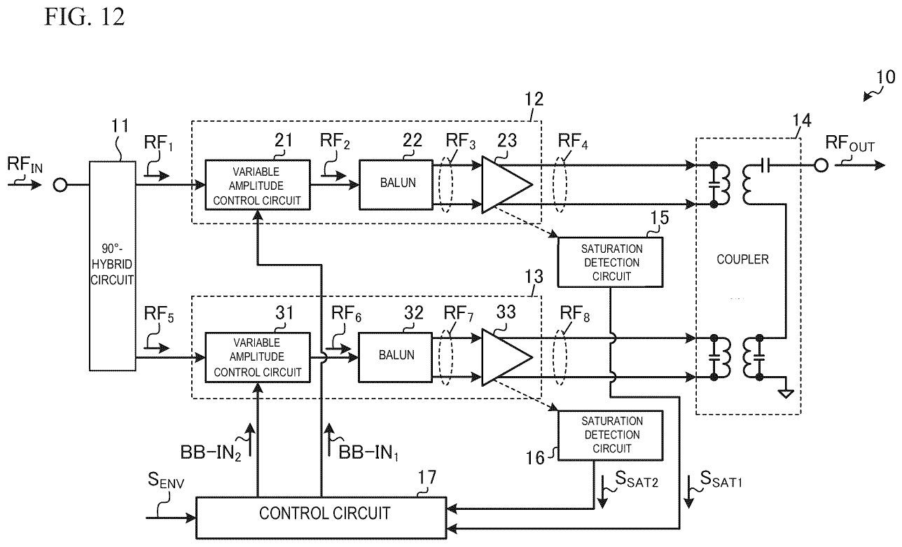

FIG. 12 is a diagram illustrating a configuration of a Doherty amplifier circuit according to the sixth embodiment.

A Doherty amplifier circuit 10 includes a 90°-hybrid circuit 11, a carrier amplifier 12, a peaking amplifier 13, a coupler 14, a saturation detection circuits 15 and 16, and a control circuit 17.

Although the number of stages in the Doherty amplifier circuit 10 is one, the present disclosure is not limited to this. The number of stages in the Doherty amplifier circuit 10 may be two or more. If a case where the number of stages in the Doherty amplifier circuit 10 is two or more, it is desirable that the carrier amplifier 12 and the peaking amplifier 13 be at a final stage.

The 90°-hybrid circuit 11 splits an input radio-frequency signal RF_{IN} into radio-frequency signals RF₁ and RF₅ that are different from each other in phase by about 90°, outputs the radio-frequency signal RF₁ to the carrier amplifier 12, and outputs the radio-frequency signal RF₅ to the peaking amplifier 13. Note that “about 90°” includes not only a phase of 90° but also a phase of 90°+45°.

The radio-frequency signal RF_{IN} corresponds to an example of “fourth radio-frequency signal” in the present disclosure. The radio-frequency signal RF₁ corresponds to an example of “fifth radio-frequency signal” in the present disclosure. The radio-frequency signal RF₅ corresponds to an example of “sixth radio-frequency signal” in the present disclosure.

An example is given in which the phase of the radio-frequency signal RF₅ is delayed by 90° with respect to the radio-frequency signal RF₁. An example is given in which the power of the radio-frequency signal RF₁ and the power of the radio-frequency signal RF₅ are the same.

The carrier amplifier 12 includes a variable amplitude control circuit 21, a balun 22, and a differential amplifier circuit 23.

The carrier amplifier 12 has a configuration similar to that of the electronic circuit 1D according to the fifth embodiment (see FIG. 11).

A circuit configuration of the variable amplitude control circuit 21 is similar to that of the variable amplitude control circuit 2 (see FIG. 5) or the variable amplitude control circuit 2B (see FIG. 9), and a description thereof is therefore omitted.

A circuit configuration of the balun 22 is similar to that of the balun 3 (see FIG. 5) or the balun 3C (see FIG. 10), and a description thereof is therefore omitted.

A circuit configuration of the differential amplifier circuit 23 is similar to that of the differential amplifier circuit 5 (see FIG. 11), and a description thereof is therefore omitted. The differential amplifier circuit 23 outputs differential signals.

The variable amplitude control circuit 21 controls an amplitude of the radio-frequency signal RF₁ in accordance with a signal BB-IN₁ input from the control circuit 17 and outputs a radio-frequency signal RF₂ to the balun 22.

The balun 22 converts the radio-frequency signal RF₂ into differential signals and outputs a pair of radio-frequency signals RF₃, which are differential signals, to the differential amplifier circuit 23.

The differential amplifier circuit 23 amplifies the pair of radio-frequency signals RF₃ and outputs a pair of radio-frequency signals RF₄, which are differential signals, to the coupler 14.

The peaking amplifier 13 includes a variable amplitude control circuit 31, a balun 32, and a differential amplifier circuit 33.

The peaking amplifier 13 has a configuration similar to that of the electronic circuit 1D according to the fifth embodiment (see FIG. 11).

A circuit configuration of the variable amplitude control circuit 31 is similar to that of the variable amplitude control circuit 2 (see FIG. 5) or the variable amplitude control circuit 2B (see FIG. 9), and a description thereof is therefore omitted.

A circuit configuration of the balun 32 is similar to that of the balun 3 (see FIG. 5) or the balun 3C (see FIG. 10), and a description thereof is therefore omitted.

A circuit configuration of the differential amplifier circuit 33 is similar to that of the differential amplifier circuit 5 (see FIG. 11), and a description thereof is therefore omitted. The differential amplifier circuit 33 outputs differential signals.

The variable amplitude control circuit 31 controls an amplitude of the radio-frequency signal RF₅ in accordance with a signal BB-IN₂ input from the control circuit 17 and outputs a radio-frequency signal RF₆ to the balun 32.

The balun 32 converts the radio-frequency signal RF₆ into differential signals and outputs a pair of radio-frequency signals RF₇, which are differential signals, to the differential amplifier circuit 33.

The differential amplifier circuit 33 amplifies the pair of radio-frequency signals RF₇ and outputs a pair of radio-frequency signals RF₈, which are differential signals, to the coupler 14.

Note that, although both the carrier amplifier 12 and the peaking amplifier 13 include the respective variable amplitude control circuits and the respective baluns, the present disclosure is not limited to this. At least one of the carrier amplifier 12 and the peaking amplifier 13 may include a variable amplitude control circuit and a balun.

The coupler 14 couples the pair of radio-frequency signals RF₄ and the pair of radio-frequency signals RF₈ and outputs a radio-frequency signal RF_{OUT}, which is a single-ended signal.

The saturation detection circuit 15 outputs, in accordance with an amplifier transistor itself or a bias circuit, a saturation signal S_{SAT1} representing the degree of saturation of the differential amplifier circuit 23 to the control circuit 17.

The saturation detection circuit 16 outputs, in accordance with an amplifier transistor itself or a bias circuit, a saturation signal S_{SAT2} representing the degree of saturation of the differential amplifier circuit 33 to the control circuit 17.

The saturation signal S_{SAT1} or the saturation signal S_{SAT2} corresponds to an example of “saturation signal” in the present disclosure.

The control circuit 17 respectively outputs the signals BB-IN₁ and BB-IN₂ to the variable amplitude control circuit 21 and the variable amplitude control circuit 31 in accordance with the saturation signals S_{SAT1} and S_{SAT2}, and at least one of envelope signals of the radio-frequency signal RF_{IN}, the radio-frequency signal RF₁, and the radio-frequency signal RF₅.

Each of the signals BB-IN₁ and BB-IN₂ corresponds to an example of “control signal” in the present disclosure.

The Doherty amplifier circuit 10 controls amplitudes of the radio-frequency signals RF₂ and RF₆ in accordance with the signals BB-IN and BB-IN₂, thereby making it possible to reduce distortions in the pair of radio-frequency signals RF₄ and the pair of radio-frequency signals RF₈.

U.S. Pat. No. 10,978,999 discloses a technique in which the gain of a variable gain amplifier in which all signals are single-ended signals is changed. However, when the variable gain amplifier is configured in which all signals are single-ended signals, in some cases, a BB signal leaks and is input to an amplifier stage, and a bias point in the amplifier stage varies, resulting in the occurrence of a distortion in an output signal.

On the other hand, when the Doherty amplifier circuit 10 is configured as described above, even if the signals BB-IN₁ and BB-IN₂ leak, the signals BB-IN₁ and BB-IN₂ are input to the differential amplifier circuits 23 and 33 as differential signals. Hence, in the Doherty amplifier circuit 10, distortions in the pair of radio-frequency signals RF₄ and the pair of radio-frequency signals RF& can be reduced by the effect of attenuating the signals BB-IN₁ and BB-IN₂ by resistors in bias circuit sections in the differential amplifier circuits 23 and 33 and the effect of cancelling out gains of a differential pair of transistors.

### Seventh Embodiment

Of components in a seventh embodiment, components that are the same as components in the other embodiments are denoted by the same reference signs, and a description thereof is omitted.

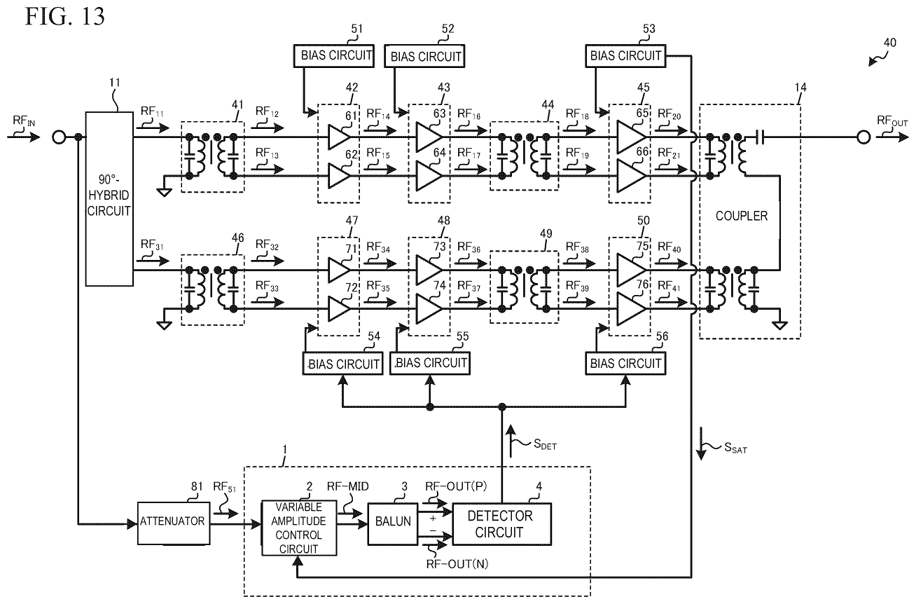

FIG. 13 is a diagram illustrating a configuration of a Doherty amplifier circuit according to the seventh embodiment.

A Doherty amplifier circuit 40 includes the electronic circuit 1, the 90°-hybrid circuit 11, baluns 41, 44, 46, and 49, a first-stage carrier amplifier 42, an intermediate-stage carrier amplifier 43, a final-stage carrier amplifier 45, a first-stage peaking amplifier 47, an intermediate-stage peaking amplifier 48, a final-stage peaking amplifier 50, bias circuits 51 to 56, the coupler 14, and an attenuator 81.

Although the number of stages in the Doherty amplifier circuit 40 is three, the present disclosure is not limited to this. The number of stages in the Doherty amplifier circuit 40 may be two or less or may be four or more.

Each of the carrier amplifiers 42, 43 and 45, and the peaking amplifiers 47, 48, and 50 is a differential amplifier.

The carrier amplifiers 42, 43, and 45 correspond to an example of “at least one-stage carrier amplifier” in the present disclosure. The peaking amplifiers 47, 48, and 50 correspond to an example of “at least one-stage peaking amplifier” in the present disclosure.

The 90°-hybrid circuit 11 splits a radio-frequency signal RF_{IN} into radio-frequency signals RF₁₁ and RF₃₁ that are different from each other in phase by about 90°, outputs the radio-frequency signal RF₁₁ to one end of a primary winding of the balun 41, and outputs the radio-frequency signal RF₃₁ to one end of a primary winding of the balun 46. The other end of the primary winding of the balun 41 and the other end of the primary winding of the balun 46 are electrically connected to the reference potential.

The radio-frequency signal RF_{IN} corresponds to an example of “fourth radio-frequency signal” in the present disclosure. The radio-frequency signal RF₁₁ corresponds to an example of “fifth radio-frequency signal” in the present disclosure. The radio-frequency signal RF₃₁ corresponds to an example of “sixth radio-frequency signal” in the present disclosure.

The balun 41 outputs radio-frequency signals RF₁₂ and RF₁₃, which are differential signals, from both respective ends of its secondary winding in accordance with the input radio-frequency signal RF₁₁.

The balun 46 outputs radio-frequency signals RF₃₂ and RF₃₃, which are differential signals, from both respective ends of its secondary winding in accordance with the input radio-frequency signal RF₃₁.

The bias circuit 51 supplies a bias to the carrier amplifier 42. A first amplifier 61 in the carrier amplifier 42 outputs a radio-frequency signal RF₁₄ obtained by amplifying the radio-frequency signal RF₁₂ to the carrier amplifier 43. A second amplifier 62 in the carrier amplifier 42 outputs a radio-frequency signal RF₁₅ obtained by amplifying the radio-frequency signal RF₁₃ to the carrier amplifier 43.

The bias circuit 52 supplies a bias to the carrier amplifier 43. A first amplifier 63 in the carrier amplifier 43 outputs a radio-frequency signal RF₁₆ obtained by amplifying the radio-frequency signal RF₁₄ to one end of a primary winding of the balun 44. A second amplifier 64 in the carrier amplifier 43 outputs a radio-frequency signal RF₁₇ obtained by amplifying the radio-frequency signal RF₁₅ to the other end of the primary winding of the balun 44.

The balun 44 outputs radio-frequency signals RF₁₈ and RF₁₉, which are differential signals, from both respective ends of its secondary winding in accordance with the input radio-frequency signals RF₁₆ and RF₁₇.

The bias circuit 53 supplies a bias to the carrier amplifier 45. A first amplifier 65 in the carrier amplifier 45 outputs a radio-frequency signal RF₂₀ obtained by amplifying the radio-frequency signal RF₁₈ to one end of a first winding on a primary side of the coupler 14. A second amplifier 66 in the carrier amplifier 45 outputs a radio-frequency signal RF₂₁ obtained by amplifying the radio-frequency signal RF₁₉ to the other end of the first winding on the primary side of the coupler 14.

The bias circuit 54 supplies a bias to the peaking amplifier 47. A first amplifier 71 in the peaking amplifier 47 outputs a radio-frequency signal RF₃₄ obtained by amplifying the radio-frequency signal RF₃₂ to the peaking amplifier 48. A second amplifier 72 in the peaking amplifier 47 outputs a radio-frequency signal RF₃₅ obtained by amplifying the radio-frequency signal RF₃₃ to the peaking amplifier 48.

The bias circuit 55 supplies a bias to the peaking amplifier 48. A first amplifier 73 in the peaking amplifier 48 outputs a radio-frequency signal RF₃₆ obtained by amplifying the radio-frequency signal RF₃₄ to one end of a primary winding of the balun 49. A second amplifier 74 in the peaking amplifier 48 outputs a radio-frequency signal RF₃₇ obtained by amplifying the radio-frequency signal RF₃₅ to the other end of the primary winding of the balun 49.

The balun 49 outputs radio-frequency signals RF₃₈ and RF₃₉, which are a pair of differential signals, from both respective ends of its secondary winding in accordance with the input radio-frequency signals RF₃₆ and RF₃₇.

The bias circuit 56 supplies a bias to the peaking amplifier 50. A first amplifier 75 in the peaking amplifier 50 outputs a radio-frequency signal RF₄₀ obtained by amplifying the radio-frequency signal RF₃₈ to one end of a second winding on the primary side of the coupler 14. A second amplifier 76 in the peaking amplifier 50 outputs a radio-frequency signal RF₄₁ obtained by amplifying the radio-frequency signal RF₃₉ to the other end of the second winding on the primary side of the coupler 14.

The bias circuits 54, 55, and 56 correspond to an example of “at least one bias circuit” in the present disclosure.

The coupler 14 couples the radio-frequency signals RF₂₀ and RF₂₁ and the radio-frequency signals RF₄₀ and RF₄₁ and outputs a radio-frequency signal RF_{OUT}.

The radio-frequency signal RF_{IN} is input to the attenuator 81. In place of the radio-frequency signal RF_{IN}, the radio-frequency signal RF₁₁ or RF₃₁ may be input to the attenuator 81. The attenuator 81 outputs a radio-frequency signal RF₅₁ obtained by attenuating the radio-frequency signal RF_{IN} (or alternatively, the radio-frequency signal RF₁₁ or RF₃₁) to the electronic circuit 1.

The attenuator 81 may be a variable attenuator that can adjust an attenuation in accordance with an external control signal. The attenuator 81 may be omitted.

The electronic circuit 1 includes the variable amplitude control circuit 2, the balun 3, and the detector circuit 4. The electronic circuit 1 may include the variable amplitude control circuit 2B (see FIG. 9) in place of the variable amplitude control circuit 2. The electronic circuit 1 may include the balun 3C (see FIG. 10) in place of the balun 3. The electronic circuit 1 may include the detector circuit 4A (see FIG. 8) in place of the detector circuit 4.

The radio-frequency signal RF₅₁ is input from the attenuator 81 to the variable amplitude control circuit 2 in the electronic circuit 1.

In place of the radio-frequency signal RF₅₁, the radio-frequency signal RF_{IN}, RF₁₁, or RF₃₁ may be input to the variable amplitude control circuit 2 in the electronic circuit 1.

In the seventh embodiment, the radio-frequency signal RF₅₁ corresponds to the radio-frequency signal RF-IN (see FIG. 5, for example).

A saturation signal S_{SAT} is input from the bias circuit 53 to the variable amplitude control circuit 2 in the electronic circuit 1. The saturation signal S_{SAT} may be input from the bias circuit 56.

The saturation signal S_{SAT} corresponds to an example of “saturation signal” in the present disclosure.

In the seventh embodiment, the saturation signal S_{SAT} corresponds to the signal BB-IN (see FIG. 5, for example).

The variable amplitude control circuit 2 outputs, to the balun 3, a radio-frequency signal RF-MID obtained by controlling, in accordance with the saturation signal S_{SAT}, an amplitude of the radio-frequency signal RF₅₁ (or alternatively, the radio-frequency signal RF_{IN}, RF₁₁, or RF₃₁, or a signal obtained by the attenuator 81 attenuating the radio-frequency signal RF_{IN}, RF₁₁, or RF₃₁).

The balun 3 outputs radio-frequency signals RF-OUT(P) and RF-OUT(N), which are differential signals into which the radio-frequency signal RF-MID has been converted, to the detector circuit 4.

The detector circuit 4 outputs a detected signal S_{DET} obtained through detection of the radio-frequency signals RF-OUT(P) and RF-OUT(N) to the bias circuits 54 to 56.

The bias circuit 54 supplies a bias to the peaking amplifier 47 in accordance with the detected signal S_{DET}. The bias circuit 55 supplies a bias to the peaking amplifier 48 in accordance with the detected signal S_{DET}. The bias circuit 56 supplies a bias to the peaking amplifier 50 in accordance with the detected signal S_{DET}.

Incidentally, it can also be considered that the variable amplitude control circuit 2 is provided as a differential circuit and is disposed between the balun 3 and the detector circuit 4.

However, it is desirable that the variable amplitude control circuit 2 be a single-ended circuit and the detector circuit 4 be a differential circuit as illustrated in FIG. 13 so that the electronic circuit 1 quickly responds to the saturation signal S_{SAT} to start the peaking amplifiers 47, 48, and 50. This is because of the following reason.

It is desirable that the detector circuit 4 be a differential circuit to implement fast detection. This is because an output signal of the detector circuit 4 is a single-ended signal. Hence, since the detector circuit 4 is a differential circuit, an output of the detector circuit 4 is a virtual ground point for a radio-frequency signal, and no large capacitor that results in time delays is necessary. In other words, the detector circuit 4 is excellent in frequency characteristics and also operates for a signal with a significantly lower frequency than a carrier frequency.

The detector circuit 4 can operate fast, whereas another characteristic of the detector circuit 4 is that the detector circuit 4 often outputting a large error if a common mode signal component (in-phase component) is input to two input terminals.

A case is examined where the variable amplitude control circuit 2 is disposed between the balun 3 and the detector circuit 4. In the variable amplitude control circuit 2, a control signal is basically a single-ended signal. For this reason, when the control signal is caused to operate fast, part of the control signal is also output to two output terminals of the variable amplitude control circuit 2 as a common mode signal component. When that signal is input to the detector circuit 4, unexpected operation of the detector circuit 4 is caused.

On the other hand, when the variable amplitude control circuit 2 is disposed in a stage preceding the balun 3 as illustrated in FIG. 13, even if part of the control signal leaks into an output signal of the variable amplitude control circuit 2, the signal that has leaked is also converted into differential signals by the balun 3. Hence, no common mode signal component is input to the detector circuit 4, and thus the detector circuit 4 does not malfunction.

### Eighth Embodiment

Of components in an eighth embodiment, components that are the same as components in the other embodiments are denoted by the same reference signs, and a description thereof is omitted.

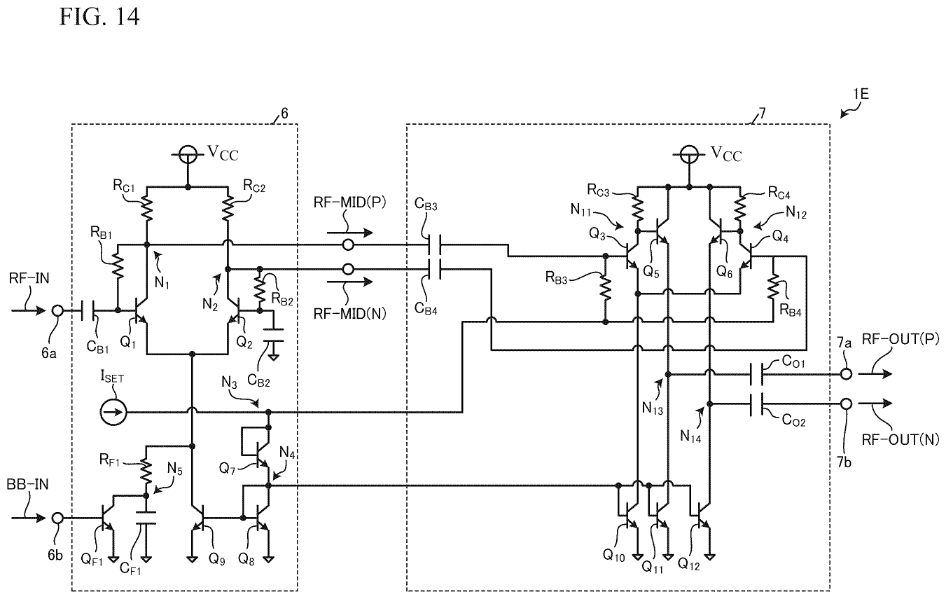

FIG. 14 is a diagram illustrating a circuit configuration of an electronic circuit according to the eighth embodiment.

An electronic circuit 1E according to the eighth embodiment is an electronic circuit obtained by modifying the electronic circuit 1A according to the second embodiment (see FIG. 8).

The electronic circuit 1E includes a variable amplitude control circuit 6 and a differential amplifier 7. The variable amplitude control circuit 6 corresponds to an integrated combination of the variable amplitude control circuit 2 and the balun 3.

The variable amplitude control circuit 6 includes a transistor Q₁, a transistor Q₂, a transistor Q₇, a transistor Q₈, a transistor Q₉, and a transistor Q_{F1}. Furthermore, the variable amplitude control circuit 6 includes a resistor R_{B1}, a resistor R_{B2}, a resistor R_{C1}, a resistor R_{C2}, and a resistor RF₁. Furthermore, the variable amplitude control circuit 6 includes a capacitor C_{B1}, a capacitor C_{B2}, a capacitor C_{F1}, and a constant current source I_{SET}.

The transistor Q₁, the resistor R_{B1}, and the capacitor C_{B1} constitute an amplifier section and correspond to the transistor Q_{AT1}, the resistor R_{AT1}, and the capacitor C_{AT1} in the variable amplitude control circuit 2 (see FIG. 8). The transistor Q₂, the resistor R_{B2}, and the capacitor C_{B2} constitute a balun section and correspond to the transistor Q_{AB2}, the resistor R_{AB4}, and the capacitor C_{AB3} in the balun 3 (see FIG. 8).

The transistors Q₁ and Q₂ are transistors constituting a differential pair. The transistors Q₇ to Q₉ are transistors that supply a bias to the transistor Q₁ and the transistor Q₂.

One end of the resistor Ra is electrically connected to the power supply potential Vcc. The other end of the resistor R_{C1} is electrically connected to a node N₁. A collector of the transistor Q₁ is electrically connected to the node N₁. The collector of the transistor Q₁ is electrically connected to the power supply potential Vcc via the resistor R_{C1} and receives a supply of power.

The node N₁ is an output node of the transistor Q₁.

One end of the resistor R_{B1} is electrically connected to the node N₁. The other end of the resistor R_{B1} is electrically connected to a base of the transistor Q₁. The base of the transistor Q₁ is electrically connected to the power supply potential Vcc via the resistors R_{C1} and R_{B1} and is biased.

The base of the transistor Q₁ is electrically connected to an input terminal 6a via the capacitor C_{B1}, which is a DC cut capacitor. A radio-frequency signal RF-IN, which is a single-ended signal, is input to the input terminal 6a.

One end of the resistor R_{C2} is electrically connected to the power supply potential Vcc. The other end of the resistor R_{C2} is electrically connected to a node N₂. A collector of the transistor Q₂ is electrically connected to the node N₂. The collector of the transistor Q₂ is electrically connected to the power supply potential Vcc via the resistor R_{C2} and receives a supply of power.

The node N₂ is an output node of the transistor Q₂.

One end of the resistor R_{B2} is electrically connected to the node N₂. The other end of the resistor R_{B2} is electrically connected to a base of the transistor Q₂. The base of the transistor Q₂ is electrically connected to the power supply potential Vcc via the resistors R_{C2} and R_{B2} and is biased. The base of the transistor Q₂ is electrically connected to the reference potential via the capacitor C_{B2}. The transistor Q₂ is base-grounded by the capacitor C_{B2}.

Thus, the transistor Q₁ and the transistor Q₂ amplify the radio-frequency signal RF-IN and output a radio-frequency signal RF-MID (P) and a radio-frequency signal RF-MID (N) to the differential amplifier 7.

A collector and a base of the transistor Q₇ are electrically connected to a node N₃. That is, the transistor Q₇ is diode-connected. An emitter of the transistor Q₇ is electrically connected to a node N₄. A collector and a base of the transistor Q₈ are electrically connected to the node N₄. That is, the transistor Q₈ is diode-connected. An emitter of the transistor Q₈ is electrically connected to the reference potential.

The constant current source I_{SET} outputs a constant current to the node N₃. This constant current flows to the transistor Q₇ and the transistor Q₈. The transistor Q₇ and the transistor Q₈ generate a fixed voltage based on the constant current. This voltage is a voltage of the node N₃. The voltage of the node N₃ is hereinafter referred to as a voltage 2Vbe.

An emitter of the transistor Q₉ is electrically connected to the reference potential. A base of the transistor Q₉ is electrically connected to the node N₄. That is, the transistor Q₈ and the transistor Q₉ are connected so as to establish a current-mirror connection. A collector of the transistor Q₉ is electrically connected to an emitter of the transistor Q₁ and an emitter of the transistor Q₂. The transistor Q₉ passes emitter currents of the transistor Q₁ and the transistor Q₂ at all times.

One end of the resistor R_{F1} is electrically connected to the emitter of the transistor Q₁ and the emitter of the transistor Q₂. The other end of the resistor R_{F1} is electrically connected to a node N₅. One end of the capacitor Cri is electrically connected to the node N₅. The other end of the capacitor C_{F1} is electrically connected to the reference potential.

A collector of the transistor Q_{F1} is electrically connected to the node N₅. An emitter of the transistor Q_{F1} is electrically connected to the reference potential. A base of the transistor Q_{F1} is electrically connected to an input terminal 6b. A signal BB-IN is input to the input terminal 6b.

The transistor Q_{F1} increases or decreases the emitter currents of the transistor Q₁ and the transistor Q₂ in accordance with the signal BB-IN.

The differential amplifier 7 includes transistors Q₃ to Q₆, and transistors Q₁₀ to Q₁₂. Furthermore, the differential amplifier 7 includes a resistor R_{B3}, a resistor R_{B4}, a resistor R_{C3}, and a resistor R_{C4}. Furthermore, the differential amplifier 7 includes a capacitor C_{B3}, a capacitor C_{B4}, a capacitor C_{O1}, and a capacitor C_{O2}.

The transistors Q₃ and Q₄ are transistors constituting a differential pair. The transistors Q₅ and Q₆ are output transistors. The transistors Q₁₀ to Q₁₂ are transistors that supply a bias to the transistors Q₃ to Q₆.

One end of the resistor R_{C3} is electrically connected to the power supply potential Vcc. The other end of the resistor R_{C3} is electrically connected to a node N₁₁. A collector of the transistor Q₃ is electrically connected to the node N₁₁. The collector of the transistor Q₃ is electrically connected to the power supply potential Vcc via the resistor R_{C3} and receives a supply of power.

The node Nu is an output node of the transistor Q₃.

One end of the resistor R_{B3} is electrically connected to the node N₃. The other end of the resistor R_{B3} is electrically connected to a base of the transistor Q₃. The base of the transistor Q₃ receives an input of the voltage 2Vbe via the resistor R_{B3} and is biased. The radio-frequency signal RF-MID (P) is input from the variable amplitude control circuit 6 to the base of the transistor Q₃ via the capacitor C_{B3}, which is a DC cut capacitor.

One end of the resistor R_{C4} is electrically connected to the power supply potential Vcc. The other end of the resistor R_{C4} is electrically connected to a node N₁₂. A collector of the transistor Q₄ is electrically connected to the node N₁₂. The collector of the transistor Q₄ is electrically connected to the power supply potential Vcc via the resistor R_{C4} and receives a supply of power.

The node N₁₂ is an output node of the transistor Q₄.

One end of the resistor R_{B4} is electrically connected to the node N₃. The other end of the resistor R_{B4} is electrically connected to a base of the transistor Q₄. The base of the transistor Q₄ receives an input of the voltage 2Vbe via the resistor R_{B4} and is biased. The radio-frequency signal RF-MID (N) is input from the variable amplitude control circuit 6 to the base of the transistor Q₄ via the capacitor C_{B4}, which is a DC cut capacitor.

A collector of the transistor Q₅ is electrically connected to the power supply potential Vcc and receives a supply of power. A base of the transistor Q₅ is electrically connected to the node N₁₁. An emitter of the transistor Q₅ is electrically connected to a node N₁₃.

The node N₁₃ is an output node of the transistor Q₅.

A collector of the transistor Q₆ is electrically connected to the power supply potential Vcc and receives a supply of power. A base of the transistor Q₆ is electrically connected to the node N₁₂. An emitter of the transistor Q₆ is electrically connected to a node N₁₄.

The node N₁₄ is an output node of the transistor Q₆.

An emitter of the transistor Q₁₀ is electrically connected to the reference potential. A base of the transistor Q₁₀ is electrically connected to the node N₄. That is, the transistor Q₈ and the transistor Q₁₀ are connected so as to establish a current-mirror connection. A collector of the transistor Q₁₀ is electrically connected to an emitter of the transistor Q₃ and an emitter of the transistor Q₄. The transistor Q₁₀ passes emitter currents of the transistor Q₃ and the transistor Q₄ at all times.

An emitter of the transistor Qu is electrically connected to the reference potential. A base of the transistor Q₁₁ is electrically connected to the node N₄. That is, the transistor Q₈ and the transistor Q₁₁ are connected so as to establish a current-mirror connection. A collector of the transistor On is electrically connected to the node N₁₃. The transistor On passes an emitter current of the transistor Q₅ at all times.

An emitter of the transistor Q₁₂ is electrically connected to the reference potential. A base of the transistor Q₁₂ is electrically connected to the node N₄. That is, the transistor Q₈ and the transistor Q₁₂ are connected so as to establish a current-mirror connection. A collector of the transistor Q₁₂ is electrically connected to the node N₁₄. The transistor Q₁₂ passes an emitter current of the transistor Q₆ at all times.

One end of the capacitor C_{O1}, which is a DC cut capacitor, is electrically connected to the node N₁₃. The other end of the capacitor C_{O1} is electrically connected to a terminal 7a. The transistor Q₅ outputs a radio-frequency signal RF-OUT(P) from the terminal 7a.

One end of the capacitor Coz, which is a DC cut capacitor, is electrically connected to the node N₁₄. The other end of the capacitor C_{O2} is electrically connected to a terminal 7b. The transistor Q₆ outputs a radio-frequency signal RF-OUT(N) from the terminal 7b.

### Effects

(1)

In the electronic circuit 1A according to the second embodiment (see FIG. 8), the signal BB-IN can leak into the radio-frequency signal RF-MID. By extension, the signal BB-IN can leak into the radio-frequency signal RF-OUT(P) and the radio-frequency signal RF-OUT(N). For this reason, if a circuit in a stage subsequent to the electronic circuit 1A is a circuit (for example, a detector circuit) that is not able to permit leakage of differential signals, it is difficult to use the electronic circuit 1A.

On the other hand, in the electronic circuit 1E according to the eighth embodiment, when the signal BB-IN is input, voltage drops occur by the same amount across the resistor R_{C1} and the resistor R_{C2}. That is, in the radio-frequency signal RF-MID (P) and the radio-frequency signal RF-MID (N), an in-phase voltage drop occurs. The differential amplifier 7 does not amplify the in-phase voltage drop and removes it. Hence, the electronic circuit 1E can keep the signal BB-IN from leaking into the radio-frequency signal RF-OUT(P) and the radio-frequency signal RF-OUT(N).

Thus, the electronic circuit 1E can be used even if a circuit in a stage subsequent to the electronic circuit 1E is a circuit that is not able to permit leakage of differential signals.

(2)

In the electronic circuit 1A according to the second embodiment, the base of the transistor Q_{AB1} is biased from the power supply potential Vcc via the resistor R_{AB3} and the resistor R_{AB1}. The base of the transistor Q_{AB3} is biased from the power supply potential Vcc via the resistor R_{AB1}. That is, the resistor R_{AB1} is shared between a base bias of the transistor Q_{AB1} and a base bias of the transistor Q_{AB3}, which is an output transistor.

In the electronic circuit 1A according to the second embodiment, the signal BB-IN can leak into the radio-frequency signal RF-MID. The radio-frequency signal RF-MID is input to the base of the transistor Q_{AB1}. Since the resistor R_{AB1} is electrically connected to the base of the transistor Q_{AB1}, a voltage or current of the resistor R_{AB1} is affected by a signal BB-IN that has leaked and varies. Thus, a base voltage or base current of the transistor Q_{AB3} varies. Hence, in the electronic circuit 1A, the signal BB-IN that has leaked is amplified by the transistor Q_{AB3} and the transistor Q_{AB4} (the gain for the leaked signal is large) and leaks into the radio-frequency signal RF-OUT(P) and the radio-frequency signal RF-OUT(N).

On the other hand, in the electronic circuit 1E according to the eighth embodiment, the base of the transistor Q₃ is biased from the node N₃ (voltage 2Vbe) via the resistor R_{B3}. The base of the transistor Q₅, which is an output transistor, is biased from the power supply potential Vcc via the resistor R_{C3}. That is, a base bias of the transistor Q₃ and a base bias of the transistor Q₅ are completely isolated from each other.

Similarly, the base of the transistor Q₄ is biased from the node N₃ (voltage 2Vbe) via the resistor R_{B4}. The base of the transistor Q₆, which is an output transistor, is biased from the power supply potential Vcc via the resistor R_{C4}. That is, a base bias of the transistor Q₄ and a base bias of the transistor Q₆ are completely isolated from each other.

The radio-frequency signal RF-MID (P) is input to the base of the transistor Q₃. Since the base bias of the transistor Q₃ and the base bias of the transistor Q₅ are completely isolated from each other, a voltage or current of the resistor R_{C3} is not affected even if the signal BB-IN leaks into the radio-frequency signal RF-MID (P).

Similarly, the radio-frequency signal RF-MID (N) is input to the base of the transistor Q₄. Since the base bias of the transistor Q₄ and the base bias of the transistor Q₆ are completely isolated from each other, a voltage or current of the resistor R_{C4} is not affected even if the signal BB-IN leaks into the radio-frequency signal RF-MID (N).

Thus, the electronic circuit 1E can keep the signal BB-IN from being amplified (can reduce the gain for the leaked signal) even if the signal BB-IN leaks into the radio-frequency signal RF-MID (P) and the radio-frequency signal RF-MID (N).

The above-described embodiments are intended to facilitate understanding of the present disclosure but are not intended for a limited interpretation of the present disclosure. The present disclosure can be changed or improved without necessarily departing from the gist thereof and also encompasses equivalents thereof.

### REFERENCE SIGNS LIST

1, 1A, 1B, 1C, 1D, 1E electronic circuit
2, 6, 2B, 2I, 31 variable amplitude control circuit
3, 3C, 22, 32, 41, 44, 46, 49 balun
4, 4A detector circuit
5, 23, 33 differential amplifier circuit
7 differential amplifier
10, 40 Doherty amplifier circuit
11 90°-hybrid circuit
12, 42, 43, 45 carrier amplifier
13, 47, 48, 50 peaking amplifier
14 coupler
15, 16 saturation detection circuit
17 control circuit
51, 52, 53, 54, 55, 56 bias circuit
81 attenuator

1. An electronic circuit comprising:
a variable amplitude control circuit configured to control an amplitude of a first radio-frequency signal, which is a single-ended signal, in accordance with a control signal that continuously changes, and that is configured to output a second radio-frequency signal that is a single-ended signal; and
a balun configured to convert the second radio-frequency signal into differential signals, and to output a pair of third radio-frequency signals.

2. The electronic circuit according to claim 1, further comprising:
a detector circuit comprising a pair of first transistors constituting a differential pair, the first transistors having bases or gates to which the pair of third radio-frequency signals are input;
wherein the detector circuit is configured to output a detected signal.

3. The electronic circuit according to claim 1, further comprising:
a differential amplifier circuit configured to amplify the pair of third radio-frequency signals.

4. The electronic circuit according to claim 3, wherein the differential amplifier circuit comprises:
a pair of second transistors constituting a differential pair, the second transistors having bases or gates to which the pair of third radio-frequency signals are input, wherein the pair of second transistors is configured to amplify the pair of third radio-frequency signals; and
a third transistor having an emitter or source from which the third transistor a bias is supplied to the bases or gates of the pair of second transistors.

5. The electronic circuit according to claim 1, wherein the variable amplitude control circuit comprises:
a fourth transistor having a base or gate to which the first radio-frequency signal is input, and an emitter or source electrically connected to an output node; and
a fifth transistor having a collector or drain electrically connected to the emitter or source of the fourth transistor, and a base or gate to which the control signal is input.

6. The electronic circuit according to claim 1, wherein the variable amplitude control circuit comprises:
a fourth transistor having a base or gate and a collector or drain electrically connected to each other, and an emitter or source that is electrically connected to an output node, the first radio-frequency signal being input to the emitter or source of the fourth transistor; and
a fifth transistor having a collector or drain electrically connected to the emitter or source of the fourth transistor, and a base or gate to which the control signal is input.

7. The electronic circuit according to claim 5, wherein the variable amplitude control circuit further comprises:
a first capacitor electrically connected between the base or gate and the collector or drain of the fifth transistor.

8. The electronic circuit according to claim 1, wherein the balun comprises:
a pair of sixth transistors constituting a differential pair, and
a second capacitor having a first end electrically connected to a base or gate of one of the pair of sixth transistors and a second end electrically connected to a reference potential,
wherein the second radio-frequency signal is input to a base or gate of another one of the pair of sixth transistors, and
wherein the pair of sixth transistors is configured to convert the second radio-frequency signal into the pair of third radio-frequency signals.

9. The electronic circuit according to claim 8, wherein the balun further comprises:
a pair of seventh transistors configured to respectively amplify the pair of third radio-frequency signals.

10. The electronic circuit according to claim 9, wherein the balun comprises:
an eighth transistor configured to supply a bias to the pair of sixth transistors, and
a ninth transistor configured to supply a bias to each of the pair of seventh transistors.

11. The electronic circuit according to claim 1, wherein the balun comprises:
a primary winding having a first end to which the second radio-frequency signal is input, and a second end connected to a reference potential or a low-impedance circuit, and
a secondary winding having a first end and a second end from which the secondary winding is configured to output the pair of third radio-frequency signals.

12. A Doherty amplifier circuit comprising:
a carrier amplifier configured to amplify a fifth radio-frequency signal split from a fourth radio-frequency signal; and
a peaking amplifier configured to amplify a sixth radio-frequency signal split from the fourth radio-frequency signal, the sixth radio-frequency signal having a different phase than the fifth radio-frequency signal,
wherein the carrier amplifier or the peaking amplifier is the electronic circuit according to claim 3.

13. The Doherty amplifier circuit according to claim 12, further comprising:
a control circuit configured to output the control signal in accordance with a saturation signal representing saturation of the carrier amplifier or the peaking amplifier, and configured to output an envelope signal of the fourth radio-frequency signal, the fifth radio-frequency signal, or the sixth radio-frequency signal.

14. A Doherty amplifier circuit comprising:
a carrier amplifier configured to amplify a fifth radio-frequency signal split from a fourth radio-frequency signal;
a peaking amplifier configured to amplify a sixth radio-frequency signal split from the fourth radio-frequency signal, the sixth radio-frequency signal having a different phase than the fifth radio-frequency signal;
a bias circuit configured to supply a bias to the peaking amplifier; and
the electronic circuit according to claim 2 configured to:
control, in accordance with a saturation signal representing saturation of the carrier amplifier or the peaking amplifier:
an amplitude of at least one of the fourth radio-frequency signal, the fifth radio-frequency signal, or the sixth radio-frequency signal, or
an amplitude of a signal obtained by attenuating at least one of the fourth radio-frequency signal, the fifth radio-frequency signal, or the sixth radio-frequency signal;
convert into differential signals:
the at least one of the fourth radio-frequency signal, the fifth radio-frequency signal, or the sixth radio-frequency signal, or
the signal obtained by attenuating at least one of the fourth radio-frequency signal, the fifth radio-frequency signal, or the sixth radio-frequency signal into differential signals;
detect the differential signals; and
output the detected signal to the bias circuit.

15. The electronic circuit according to claim 6, wherein the variable amplitude control circuit further comprises:
a first capacitor connected between the base or gate and the collector or drain of the fifth transistor.

16. A Doherty amplifier circuit comprising:
a carrier amplifier configured to amplify a fifth radio-frequency signal split from a fourth radio-frequency signal; and
a peaking amplifier configured to amplify a sixth radio-frequency signal split from the fourth radio-frequency signal, the sixth radio-frequency signal having a different phase than the fifth radio-frequency signal,
wherein the carrier amplifier or the peaking amplifier is the electronic circuit according to claim 4.
